(19) United States
(12) Patent Application Publication
(10) Pub. No.: US 2022/0284962 A1
(43) Pub. Date: Sep. 8, 2022

(54) MEMORY SYSTEM

(71) Applicant: Kioxia Corporation, Tokyo (JP)

(72) Inventors: Kazutaka IKEGAMI, Inagi (JP); Takashi MAEDA, Kamakura (JP)

(73) Assignee: Kioxia Corporation, Tokyo (JP)

(21) Appl. No.: 17/445,614

(22) Filed: Aug. 23, 2021

(30) Foreign Application Priority Data
Mar. 5, 2021 (JP) 2021-035320

(51) Int. Cl. G11C 16/08; G11C 16/10; G11C 16/14; G11C 16/26; G11C 16/34; G11C 16/04

(52) U.S. Cl. CPC G11C 16/08; G11C 16/102; G11C 16/14; G11C 16/26; G11C 16/3404; G11C 16/0433

(57) ABSTRACT

A memory system according to an embodiment includes first to sixth word lines, a plurality of memory pillars and a control circuit. The control circuit performs an initial write operation in which a threshold voltage of a subject memory cell is increased from a first level to a second level, a first write operation after the initial write operation and a second write operation after the first write operation. The control circuit is configured to perform the initial write operation on the third memory cell and the fourth memory cells, the first write operation on the third memory cells, the first write operation on the fourth memory cells, the second write operation on the fifth memory cells, the second write operation on the sixth memory cells, and the initial write operation on the first memory cells and the second memory cells.

### CROSS REFERENCE TO RELATED APPLICATIONS

This application is based upon and claims the benefit of priority from the prior Japanese Patent Application No. 2021-035320 filed on Mar. 5, 2021, the entire contents of which are incorporated herein by reference.

### FIELD

Embodiments of the present disclosures relate to a memory system provided with a semiconductor storage device.

### BACKGROUND

A memory system, which includes a NAND-type flash memory as a semiconductor storage device and a controller, which controls the NAND-type flash memory, is known.

### BRIEF DESCRIPTION OF DRAWINGS

FIG. 1 is a block diagram illustrating a power supply system of a memory system according to an embodiment;

FIG. 2 is a block diagram illustrating a signal system of a memory system according to an embodiment;

FIG. 3 is a block diagram illustrating a configuration of a semiconductor storage device according to an embodiment;

FIG. 4 is a diagram illustrating a circuit configuration of a memory cell array of a semiconductor storage device according to an embodiment;

FIG. 5 is a diagram illustrating a layout of select gate lines, bit lines, and memory pillars of a semiconductor storage device according to an embodiment;

FIG. 6 is a diagram illustrating a layout of word lines and memory pillars of a semiconductor storage device according to an embodiment;

FIG. 7 is a A-A′ cross-sectional view of the semiconductor storage device shown in FIG. 6;

FIG. 8 is a B-B′ cross-sectional view of the semiconductor storage device shown in FIG. 6;

FIG. 9 is a C-C′ cross-sectional view of the memory cell shown in FIG. 7;

FIG. 10 is a D-D′ cross-sectional view of the memory cell shown in FIG. 9;

FIG. 11 is a modification of the memory cell shown in FIG. 9;

FIG. 12 is an E-E′ cross-sectional view of the memory cell shown in FIG. 11;

FIG. 13 shows adjacent strings in a semiconductor storage device according to an embodiment;

FIG. 14 is a diagram illustrating a threshold distribution of a memory cell transistor according to an embodiment;

FIG. 15 is a diagram illustrating a two-layers cut-off read operation in a semiconductor storage device according to an embodiment;

FIG. 16 is a diagram illustrating a three-layers cut-off read operation in a semiconductor storage device according to an embodiment;

FIG. 17 is a diagram illustrating a verify operation in a semiconductor storage device according to an embodiment;

FIG. 18 is a diagram illustrating an over-erased cell write operation in a semiconductor storage device according to an embodiment;

FIG. 19 is a diagram illustrating a two-stages write operation in a semiconductor storage device according to an embodiment;

FIG. 20 is a diagram illustrating a three-stages write operation in a semiconductor storage device according to an embodiment;

FIG. 21 is a diagram illustrating a write operation referring to a layout of word lines and memory pillars of a semiconductor storage device according to an embodiment;

FIG. 22 is a diagram illustrating a write operation referring to a layout of word lines and memory pillars of a semiconductor storage device according to an embodiment;

FIG. 23 is a diagram illustrating a write operation referring to a layout of word lines and memory pillars of a semiconductor storage device according to an embodiment;

FIG. 24 is a diagram illustrating a write operation referring to a layout of word lines and memory pillars of a semiconductor storage device according to an embodiment;

FIG. 25 is a diagram illustrating how a target memory cell receives interference caused by a write operation to another memory cell in a semiconductor storage device according to an embodiment;

FIG. 26 is a diagram illustrating a write order in a semiconductor storage device according to an embodiment;

FIG. 27 is a diagram illustrating a write order in a semiconductor storage device according to an embodiment;

FIG. 28 is a diagram illustrating a write order in a semiconductor storage device according to an embodiment;

FIG. 29 is a diagram illustrating a write order in a semiconductor storage device according to an embodiment;

FIG. 30 is a diagram illustrating a batch EP operation and a batch verify operation in a semiconductor storage device according to an embodiment;

FIG. 31 is a diagram illustrating a verify operation in a semiconductor storage device according to an embodiment;

FIG. 32 is a diagram illustrating a batch EP operation and a batch verify operation in a semiconductor storage device according to an embodiment; and

FIG. 33 is a diagram illustrating a batch EP operation and a batch verify operation in a semiconductor storage device according to an embodiment.

### DETAILED DESCRIPTION

A memory system according to an embodiment includes: a first word line provided in a first layer; a second word line provided in the first layer and configured to be controlled independently from the first word line; a third word line provided in a second layer being adjacent to the first layer in a vertical direction; a fourth word line provided in the second layer and configured to be controlled independently from the third word line; a fifth word line provided in a third layer being adjacent to the second layer in the vertical direction; a sixth word line provided in the third layer and configured to be controlled independently from the fifth word line; and a plurality of memory pillars. Each of the plurality of memory pillars extends in the vertical direction to be sandwiched by the first word line and the second word line, sandwiched by the third word line and the fourth word line, and sandwiched by the fifth word line and the sixth word line. Each of the plurality of memory pillars includes a first memory cell facing the first word line, a second memory cell facing the second word line, a third memory cell facing the third word line, a fourth memory cell facing the fourth word line, a fifth memory cell facing the fifth word line and a sixth memory cell facing the sixth word line. The control circuit is configured to perform an initial write operation in which a threshold voltage of a subject memory cell is increased from a first level to a second level, the first level corresponding to an erased state, the second level corresponding to a level no less than a minimum voltage supplied in a read operation, a first write operation after the initial write operation and a second write operation after the first write operation. The control circuit is configured to perform the initial write operation on the third memory cells and the fourth memory cells, the first write operation on the third memory cells, the first write operation on the fourth memory cells, the second write operation on the fifth memory cells, the second write operation on the sixth memory cells, and the initial write operation on the first memory cells and the second memory cells.

Hereinafter, a non-volatile semiconductor storage device according to the present embodiments are described in detail by referring to the drawings. In the following description, elements having substantially the same functions and configurations are denoted by the same reference numerals and are described redundantly only when necessary. Each of the embodiments described below exemplifies a device and a method for embodying the technical idea of this embodiment. The technical idea of the embodiment is not limited as the material, shape, structure, arrangement and the like of the constituent parts described below. Various modifications may be made to the technical idea of the embodiment in addition to the scope of the claims.

Further, in the following description, signals X<n:0> (“n” is a natural number) are made up of (n+1)-bit signals, and mean a group of signals X<0>, X<1>, . . . , and X<n>, each of which is a 1-bit signal. In addition, elements Y<n:0> mean a group of elements Y<0>, Y<1>, . . . , and Y<n>, which correspond to the input or output of the signals X<n:0> in a one-to-one relationship.

In the following description, a signal BZ indicates that it is an inverted signal of a signal Z. Alternatively, when the signal Z is a control signal, the signal Z is a positive logic and the signal BZ is a negative logic. That is, the “H” level of the signal Z corresponds to assertion, and the “L” level of the signal Z corresponds to negation. The “L” level of the signal BZ corresponds to assertion, and the “H” level of the signal Z corresponds to negation.

In the following description, the notation A/B means A or B. For example, “X includes A/B, C/D and E” includes the case “X includes A, C and E” and “X includes B, D and E”.

### 1. First Embodiment

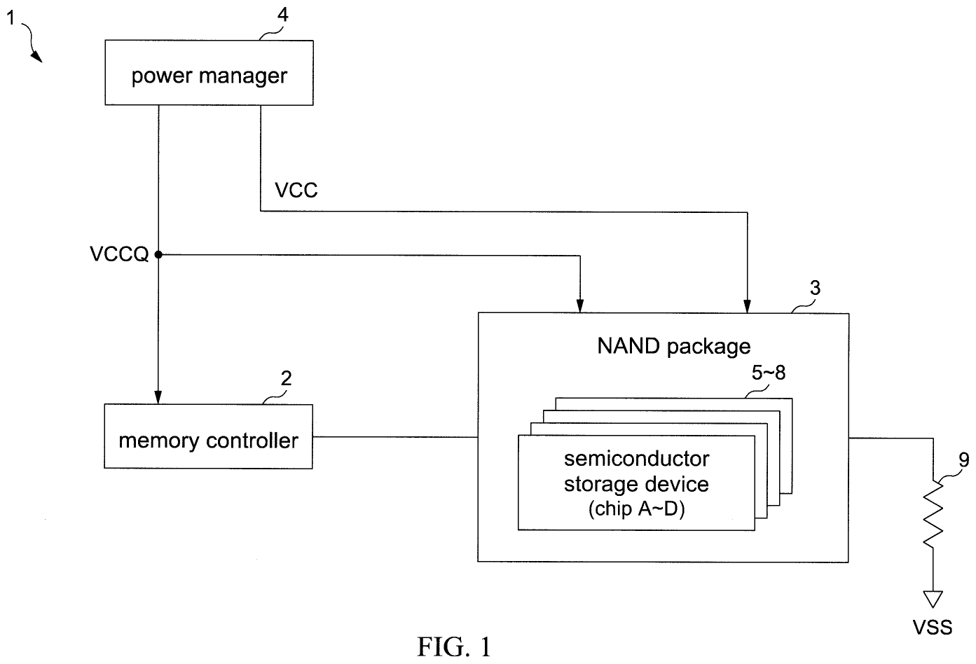

A memory system according to a first embodiment is described with reference to the FIGS. 1 to 21. The memory system according to the first embodiment includes, for example, a NAND-type flash memory as a semiconductor storage device and memory controller which controls the NAND-type flash memory.

### 1-1. OVERALL CONFIGURATION OF THE MEMORY SYSTEM

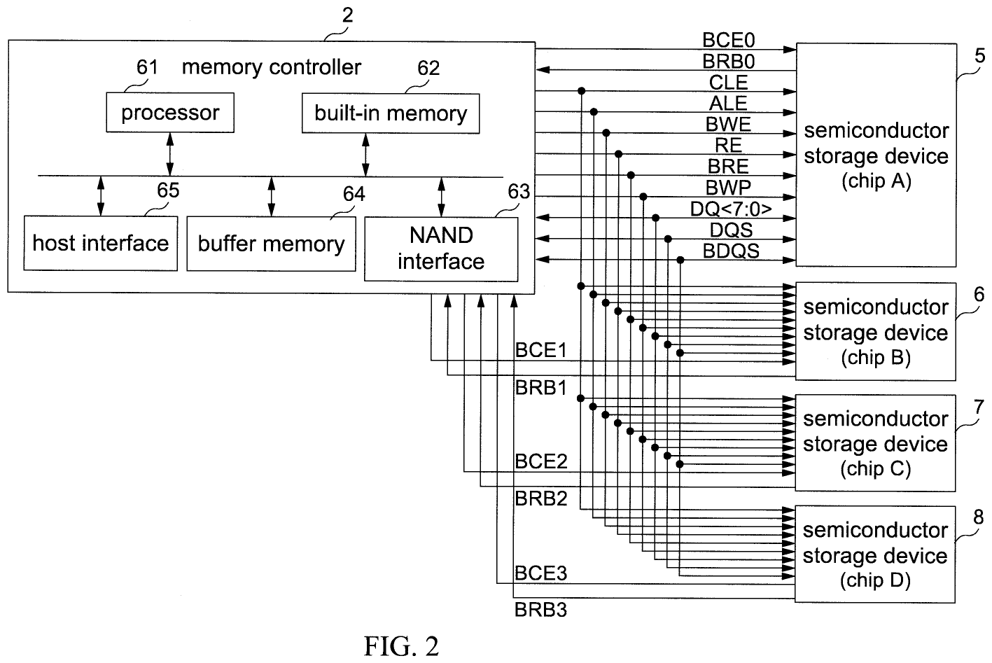

The overall configuration of the memory system according to the first embodiment is described with reference to FIGS. 1 and 2. A memory system 1 communicates with, for example, an external host device (not illustrated). The memory system 1 holds data received from the host device and transmits data which read from the semiconductor storage devices 5 to 8 to the host device.

FIG. 1 is a diagram for explaining a power supply system of the memory system according to the first embodiment. As shown in FIG. 1, the memory system 1 includes a memory controller 2, a NAND package 3, a power manager 4 and a reference resistance 9. The NAND package 3 includes, for example, a plurality of semiconductor storage devices 5 to 8. In FIG. 1, four chips are included in the NAND package 3. In the following discussion, the semiconductor storage devices 5 to 8 may be read as chips A to D, respectively.

The power manager 4 is an integrated circuit (IC) for managing the voltage to be supplied to the memory controller 2 and the NAND package 3. The power manager 4 supplies, for example, a voltage VCCQ to the memory controller 2 and the NAND package 3. The voltage VCCQ is used as a reference of the voltage that is used for an input/output signal between the memory controller 2 and the NAND package 3. In addition, the power manager 4 supplies, for example, a voltage VCC to the NAND package 3. The voltage VCC is used as a reference voltage of other voltages used in the NAND package 3.

In addition, the NAND package 3 is connected to a voltage VSS via the reference resistor 9. The reference resistor 9 is used, for example, to calibrate an output impedance of each of the semiconductor storage devices 5 to in the NAND package 3. The voltage VSS is a ground voltage, and is defined as, for example, ground (0V) in the memory system 1.

FIG. 2 is a block diagram for explaining a configuration of a signal system of a memory system according to an embodiment. As shown in FIG. 2, the memory controller 2 controls the semiconductor storage devices 5 to 8. Specifically, the memory controller 2 writes data to the semiconductor storage devices 5 to 8 and reads data from the semiconductor storage devices 5 to 8. The memory controller 2 is connected to the semiconductor storage devices 5 to 8 by a NAND bus.

Each of the semiconductor storage devices 5 to 8 includes a plurality of memory cells and stores data in a non-volatile manner. Each the semiconductor storage devices 5 to 8 is a semiconductor chip that can be uniquely identified, for example, by being supplied with an individual chip enable signal or by being pre-assigned with an individual chip address. Therefore, each of the semiconductor storage devices 5 to 8 can be operated independently according to instructions of the memory controller 2.

Similar signals are transmitted and received on the NAND bus connected to each of the semiconductor storage devices 5 to 8. The NAND bus includes a plurality of signal lines to transmit and receive signals according to a NAND interface. BCE is a chip enable signal and operates with negative logic. BRB is a ready busy signal and operates in negative logic. CLE is a command latch enable signal and operates in positive logic. ALE is an address latch enable signal and operates in positive logic. BWE is a write enable signal and operates in negative logic. RE and BRE are read enable signals and inverted signals of them. The RE operates in positive logic. The BRE operates in negative logic. For example, the RE and/or BRE function as output instruction signals. BWP is a write protect signal and operates in negative logic.

DQ<7:0> is a data signal. The data signal DQ<7:0> is input and output via the input/output terminal (I/O port). Signals DQS and BDQS are a data strobe signal and an inverted signal of the data strobe signal. For example, the DQS and/or the BDQS function as the strobe signal or a timing control signal. The strobe signal (DQS/BDQS) is a signal pair having opposite phases. The strobe signal is a signal defining timing of transmitting and receiving the data signal DQ<7:0>. Signals BCE0 to BCE3 are transmitted from the memory controller 2 to each of the storage devices 5 to 8 independently. Signals BRB0 to BRB3 are transmitted independently from each of the semiconductor storage devices 5 to 8 to the memory controller 2. The signals CLE, ALE, BWE, RE, BRE and BWP are commonly transmitted from the memory controller 2 to the semiconductor storage devices 5 to 8.

The signals BCE0 to BCE3 are signals for enabling the semiconductor storage devices 5 to 8, respectively. The signal CLE notifies the semiconductor storage devices 5 to 8 that the data signals DQ<7:0> flowing to the semiconductor storage devices 5 to 8 are commands while the signal CLE is at the “high (H)” level. The signal ALE notifies the semiconductor storage devices 5 to 8 that the data signals DQ<7:0> flowing to the semiconductor storage devices 5 to 8 are addresses while the signal ALE is at the “H” level. The signal BWE instructs the semiconductor storage devices 5 to 8 to write the data signals DQ<7:0> flowing to the semiconductor storage devices 5 to 8 while the signal BWE is at the “low (L)” level.

The signals RE and BRE instruct the semiconductor storage devices 5 to 8 to output the data signals DQ<7:0>, and for example, are used to control the operation timing of the semiconductor storage devices 5 to 8 when outputting the data signals DQ<7:0>. The signal BWP instructs the semiconductor storage devices 5 to 8 to prohibit data writing and erasing. The signals BRB0 to BRB3 respectively indicate whether the semiconductor storage devices 5 to 8 are in a ready state (a state of accepting a command from the outside) or in a busy state (a state of not accepting a command from the outside).

The data signals DQ<7:0> are, for example, 8-bit signals. The data signals DQ<7:0> are transmitted and received between the semiconductor storage devices 5 to 8 and the memory controller 2, and include commands, addresses, and data. The signals DQS and BDQS may be generated, for example, based on the signals RE and BRE, and are used to control the operation timing of the semiconductor storage devices 5 to 8 in response to the data signals DQ<7:0>.

The memory controller 2 includes a processor (central processing unit (CPU)) 61, a built-in memory (random access memory (RAM)) 62, a NAND interface circuit 63, a buffer memory 64 and a host interface circuit 65.

The processor 61 controls the overall operation of the memory controller 2. The processor 61 issues, for example, a write command based on a NAND interface to the semiconductor storage devices 5 to 8 in response to a write command of data received from the outside. This function is equally applied to other operations such as, for example, read, erasing and calibration operations.

The built-in memory 62 is, for example, a semiconductor memory such as, for example, dynamic RAM (DRAM), and is used as a work area of the processor 61. The built-in memory 62 holds, for example, firmware and various management tables for managing the semiconductor storage devices 5 to 8.

The NAND interface circuit 63 is connected to the semiconductor storage devices 5 to 8 via the above-described NAND bus, and executes communication with the semiconductor storage devices 5 to 8. The NAND interface circuit 63 transmits commands, addresses, and write data to the semiconductor storage devices 5 to 8 in response to an instruction of the processor 61. In addition, the NAND interface circuit 63 receives statuses and read data from the semiconductor storage devices 5 to 8.

The buffer memory 64 temporarily holds, for example, data received by the memory controller 2 from the semiconductor storage devices 5 to 8 and the outside.

The host interface circuit 65 is connected to an external host device (not illustrated), and executes communication with the host device. The host interface circuit 65 transfers, for example, commands and data, received from the host device to the processor 61 and the buffer memory 64, respectively.

### 1-2. CONFIGURATION OF THE SEMICONDUCTOR STORAGE DEVICE

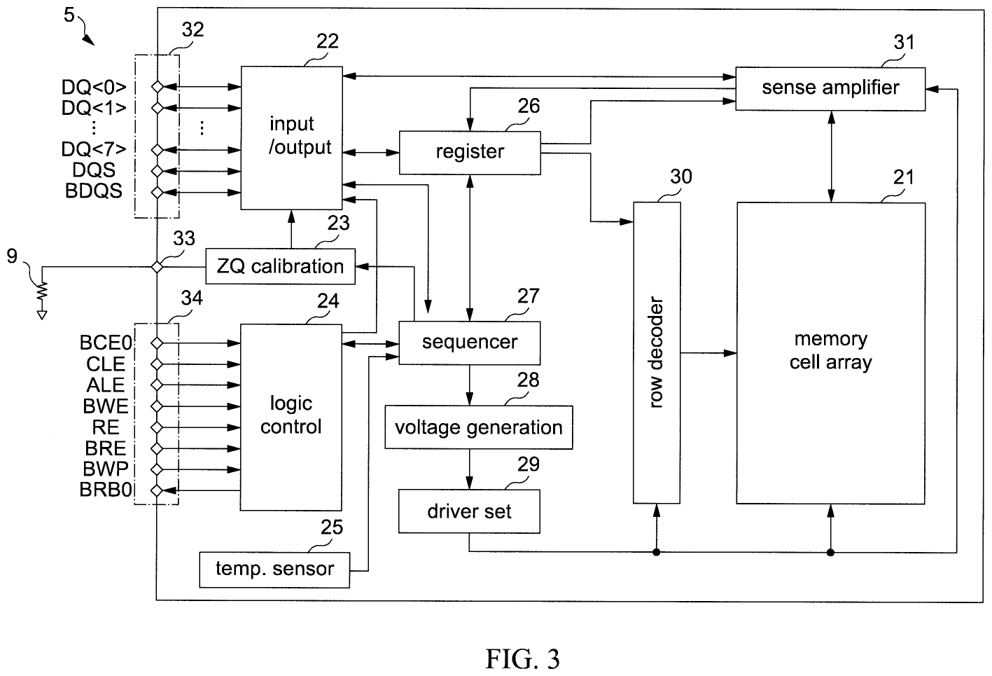

The configuration of the semiconductor storage device according to the first embodiment is described with reference to FIG. 3. The semiconductor storage devices 5 to 8 have, for example, the same configuration. Therefore, in the following description, a configuration of the semiconductor storage device 5, among the semiconductor storage devices 5 to 8, is described, and a description related to a configuration of the semiconductor storage devices 6 to 8 is omitted.

As illustrated in FIG. 3, the semiconductor storage device 5 includes a memory cell array 21, an input/output circuit 22, a ZQ calibration circuit 23, a logic control circuit 24, a temperature sensor 25 (temp. sensor), a register 26, a sequencer 27, a voltage generation circuit 28, a driver set 29, a row decoder 30, a sense amplifier 31, an input/output pad group 32, a ZQ calibration pad 33 and a logic-control pad group 34.

The memory cell array 21 includes a plurality of nonvolatile memory cells (not illustrated) associated with word lines and bit lines.

The input/output circuit 22 transmits and receives the data signals DQ<7:0> to and from the memory controller 2. The input/output circuit 22 transfers commands and addresses in the data signals DQ<7:0> to the register 26. The input/output circuit 22 transmits and receives write data and read data to and from the sense amplifier 31.

The ZQ calibration circuit 23 calibrates the output impedance of the semiconductor storage device 5 based on the reference resistor 9 via the ZQ calibration pad 33.

The logic control circuit 24 receives the signals BCE0, CLE, ALE, BWE, RE, BRE and BWP from the memory controller 2. In addition, the logic control circuit 24 transfers the signal BRB0 to the memory controller 2 and notifies the state of the semiconductor storage device 5 to the outside.

The temperature sensor 25 measures the temperature inside the semiconductor storage device 5. The temperature sensor 25 sends information on the measured temperature to the sequencer 27. Further, the temperature sensor 25 may be provided at any position in the semiconductor storage device 5 in a range within which it may measure the temperature that may be regarded as the temperature of the memory cell array 21.

The register 26 holds commands and addresses. The register 26 transfers the addresses to the row decoder 30 and the sense amplifier 31, and transfers the commands to the sequencer 27.

The sequencer 27 receives the commands, and controls the entire semiconductor storage device 5 according to the sequence based on the received commands. In addition, the sequencer 27 sends information on the temperature, received from the temperature sensor 25, to the memory controller 2 via the input/output circuit 22.

The voltage generation circuit 28 generates voltages required for operations such as, for example, data writing, reading and erasing based on an instruction from the sequencer 27. The voltage generation circuit 28 supplies the generated voltage to the driver set 29.

The driver set 29 includes a plurality of drivers, and supplies various voltages from the voltage generation circuit 28 to the row decoder 30 and the sense amplifier 31 based on the addresses from the register 26. The driver set 29 supplies various voltages to the row decoder 30 based on, for example, a row address among the addresses.

The row decoder 30 receives the row address, among the addresses, from the register 26, and selects the memory cells in the row based on the row address. Then, the voltages from the driver set 29 are transferred to the memory cells in the selected row via the row decoder 30.

At the time of reading data, the sense amplifier 31 senses read data that are read from the memory cells to the bit lines, and transfers the sensed read data to the input/output circuit 22. At the time of writing data, the sense amplifier 31 transfers write data via the bit lines to the memory cells. In addition, the sense amplifier 31 receives a column address, among the addresses, from the register 26, and outputs column data based on the column address.

The input/output pad group 32 transfers the data signal DQ<7:0>, the signal DQS and the signal BDQS, received from the memory controller 2, to the input/output circuit 22. In addition, the input/output pad group 32 transfers the data signal DQ<7:0>, transmitted from the input/output circuit 22, to the outside of the semiconductor storage device 5.

The ZQ calibration pad 33 is connected at one end thereof to the reference resistor 9 and at the other end thereof to the ZQ calibration circuit 23.

The logic control pad group 34 transfers signals BCE0, CLE, ALE, BWE, RE, BRE and BWP received from the memory controller 2 to the logic control circuit 24. The logic control pad group 34 transfers BRB0 transmitted from the logic control circuit 24 to the external of the semiconductor storage device 5.

### 1-3. CONFIGURATION OF MEMORY CELL ARRAY 21

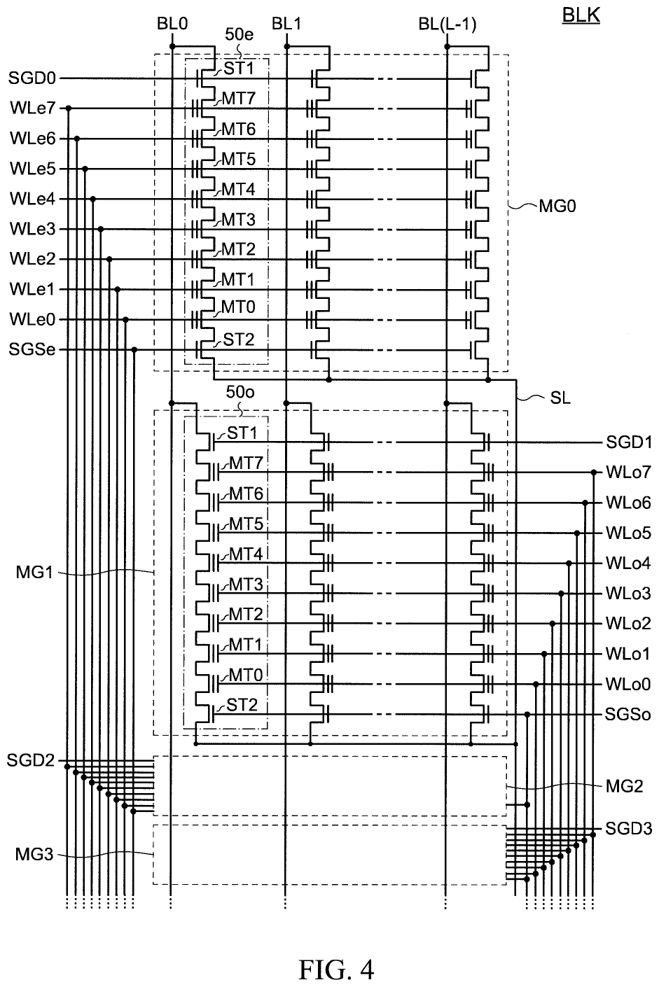

The circuit configuration of the memory cell array 21 will be described with reference to FIG. 4. FIG. 4 is an equivalent circuit diagram of a block BLK. As shown in FIG. 4, the block BLK includes a plurality of memory groups MG (MG0, MG1, MG2, . . . ). Each memory group MG includes a plurality of NAND strings 50. In the following description, a NAND string of an even-numbered memory group MGe (MG0, MG2, MG4, . . . ) is referred to as a NAND string 50e. A NAND string of an odd-numbered memory group MGo (MG1, MG3, MG5, . . . ) is referred to as a NAND string 50o.

Each of the NAND strings 50 includes, for example, eight memory cell transistors MT (MT0 to MT7) and select transistors ST1 and ST2. The memory cell transistor MT includes a control gate and a charge storage layer. The memory cell transistor MT has a threshold voltage and is in an on-state when a voltage equal to or higher than the threshold voltage is applied to the control gate. When a write operation to the memory cell transistor MT is performed, the threshold voltage of the memory cell transistor MT varies. That is, the threshold voltage of the memory cell transistor MT varies when electrons are injected into the charge storage layer of the memory cell transistor MT. The threshold voltage of the memory cell transistor MT in a state where electrons are injected into the charge storage layer is higher than the threshold voltage of the memory cell transistor MT in a state where no electrons are injected into the charge storage layer. The memory cell transistor MT holds data non-volatile by variations of the threshold voltage due to the injection of electrons into the charge storage layer. The eight memory cell transistors MT are connected in series between a source of the select transistor ST1 and a drain of the select transistor ST2.

Gates of the select transistor ST1 in each of the memory groups MG are connected to select gate lines SGD (SGD0, SGD1, . . . ) respectively. Each select gate line SGD is independently controlled by the row decoder 30. Gate of the select transistor ST2 in each of the even-numbered memory groups MGe (MG0, MG2, . . . ) are commonly connected to a select gate line SGSe. Gate of the select transistor ST2 in each of the odd-numbered memory groups MGo (MG1, MG3, . . . ) are commonly connected to a select gate line SGSo. The select gate lines SGSe and SGSo may be commonly connected or independently controllable.

The control gates of the memory cell transistors MT (MT0 to MT7) included in the memory group MGe in the same block BLK are commonly connected to word lines WLe (WLe0 to WLe7), respectively. On the other hand, the control gates of the memory cell transistors MT (MT0 to MT7) included in the memory group MGo are commonly connected to word lines WLo (WLo0 to WLo7), respectively. The word lines WLe and WLo are independently controlled by the row decoder 30.

The block BLK is, for example, an erasure unit of data. That is, data held by the memory cell transistors MT included in the same block BLK are collectively erased. The threshold voltage of the memory cell transistor MT in an erased state is lower than the threshold voltage of the memory cell transistor MT in a written state.

In the memory cell array 21, the drains of the select transistors ST1 included in the NAND strings 50 provided in the same column are commonly connected to a bit line BL (BL0 to BL(L−1)). L is a natural number of 2 or more. That is, the bit lines BL are commonly connected to the NAND strings between the plurality of memory groups MG. In the memory cell array 21, the sources of the plurality of select transistors ST2 are commonly connected to a source line SL.

The memory group MG includes the plurality of NAND strings 50. The plurality of NAND strings 50 are connected to different bit lines BL and connected to the same select gate line SGD. The block BLK includes the plurality of memory groups MG sharing the word line WL. The memory cell array includes a plurality of blocks BLK sharing the bit line BL. In the memory cell array 21, the select gate line SGS, the word line WL, and the select gate line SGD are stacked above a semiconductor substrate so that the memory cell transistor MT is stacked in three dimensions.

### <Planar Layout of Memory Cell Array>

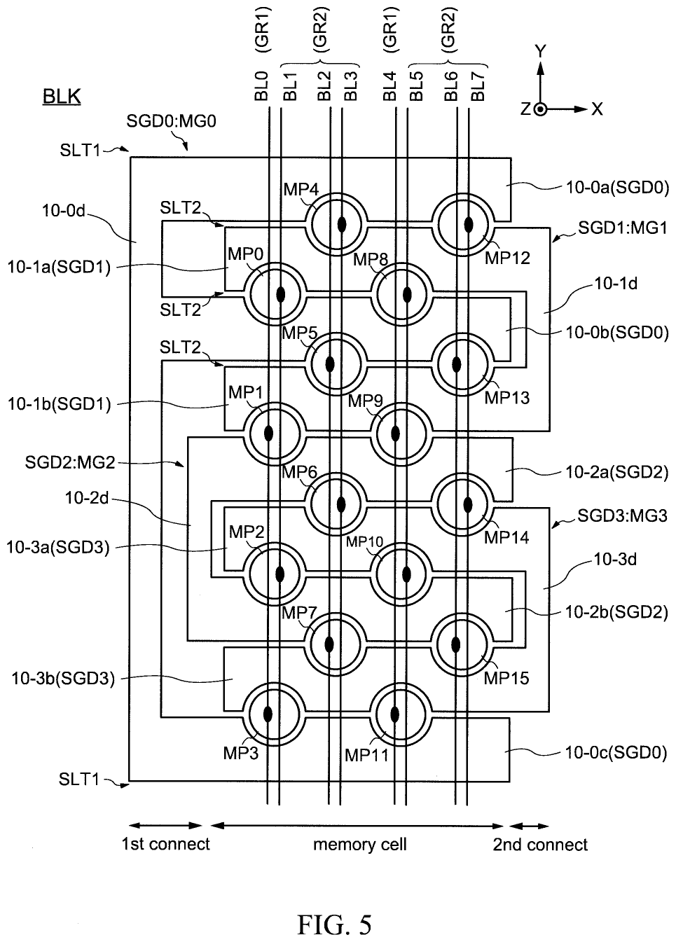

A planar configuration of the memory cell array 21 will be described with reference to FIG. 5. FIG. 5 shows a planar layout of the select gate line SGD in a semiconductor substrate plane (X-Y plane) of certain block BLK. In the present embodiment, a configuration in which four select gate lines SGD are included in one block BLK is described.

As shown in FIG. 5, wiring layers 10-0a, 10-0b, 10-0c having a longitudinal in the X-direction are connected by a first connecting section 10-0d (1st connect) having a longitudinal in the Y-direction. The two wiring layers 10-0a, 10-0c are provided at both ends in the Y-direction. The wiring layers 10-0a, 10-0b are adjacent to each other in the Y-direction with the other one wiring layer (a wiring layer 10-1a) interposed therebetween. The first connecting section 10-0d is provided at the first end in the X-direction. Three wiring layers 10-0a, 10-0b, 10-0c function as the select gate line SGD0.

The wiring layers 10-1a, 10-1b having the longitudinal in the X-direction are connected by a second connecting section 10-1d (2nd connect) having the longitudinal in the Y-direction. The wiring layer 10-1a is provided between the wiring layers 10-0a, 10-0b. The wiring layer 10-1b is provided between the wiring layer 10-0b and the other one wiring layer (a wiring layer 10-2a). The second connecting section 10-1d is provided on the second end which is the opposite side of the first connecting section 10-0d in the X-direction. The two wiring layers 10-1a, 10-1b function as the select gate line SGD1.

The wiring layers 10-2a, 10-2b having the longitudinal in the X-direction are connected by a first connecting section 10-2d having the longitudinal in the Y-direction. Similarly, wiring layers 10-3a, 10-3b having the longitudinal in the X-direction are connected by a second connecting section 10-3d having the longitudinal in the Y-direction. The wiring layer 10-2a is provided between the wiring layer 10-1b and the wiring layer 10-3a. The wiring layer 10-3a is provided between the wiring layer 10-2a and the wiring layer 10-2b. The wiring layer 10-2b is provided between the wiring layer 10-3a and the wiring layer 10-3b. The wiring layer 10-3b is provided between the wiring layer 10-2b and the wiring layer 10-0c. The first connecting section 10-2d is provided at a first end in the X-direction. The second connecting section 10-3d is provided at a second end in the X-direction. In the X-direction, the first end is an end portion on the same side as the first connect 10-0d, the second end is an end portion on the opposite side of the first connect 10-0d. The two wiring layers 10-2a, 10-2b function as the select gate line SGD2. The two wiring layers 10-3a, 10-3b function as the select gate line SGD3.

In the present embodiment, a configuration in which each wiring layer is connected by the first connecting sections 10-0d, 10-2d, or the second connecting sections 10-1d, 10-3d is exemplified but is not limited to this configuration. For example, each wiring layer may be independent and controlled so that the same voltage is supplied to the wiring layers 10-0a, 10-0b, 10-0c, the same voltage is supplied to the wiring layers 10-1a, 10-1b, the same voltage is supplied to the wiring layers 10-2a, 10-2b, and the same voltage is supplied to the wiring layers 10-3a, 10-3b.

A group including a memory pillar MP adjacent to the wiring layers 10-0a, 10-0b, 10-0c is referred to as the memory group MG0. A group including the memory pillar MP adjacent to the wiring layers 10-1a, 10-1b is referred to as the memory group MG1. A group including the memory pillar MP adjacent to the wiring layers 10-2a, 10-2b is referred to as the memory group MG2. A group including the memory pillar MP adjacent to the wiring layers 10-3a, 10-3b is referred to as the memory group MG3.

The wiring layers 10 adjacent to each other in the Y-direction in the block BLK are insulated. An area that insulates the adjacent wiring layers 10 is referred to as a slit SLT2. In the slit SLT2, for example, an insulation layer is embedded in an area from a surface of the semiconductor substrate to a layer where at least the wiring layer 10 is provided. In the memory cell array 21, for example, the plurality of blocks BLK shown in FIG. 5 is arranged, in the Y-direction. Between the blocks BLK adjacent to each other in the Y-direction is also insulated in the same manner as described above. An area that insulates the adjacent blocks BLK is referred to as a slit SLT1. The slit SLT1 have the same configuration as the slit SLT2.

The plurality of memory pillars MP (MP0 to MP15) is provided between the wiring layers 10 adjacent to each other in the Y-direction. Each of the plurality of memory pillars MP has the longitudinal in the Z-direction. The Z-direction is a direction orthogonal (or intersecting) to the X-Y direction, i.e., a direction orthogonal to the surface of the semiconductor substrate. The plurality of memory pillars MP is provided in a memory cell section (memory cell).

Specifically, the memory pillars MP4, MP12 are provided between the wiring layers 10-0a, 10-1a. The memory pillars MP0, MP8 are provided between the wiring layers 10-1a, 10-0b. The memory pillars MP5, MP13 are provided between the wiring layers 10-0b, 10-1b. The memory pillars MP1, MP9 are provided between the wiring layers 10-1b, 10-2a. The memory pillars MP6, MP14 are provided between the wiring layers 10-2a, 10-3a. The memory pillars MP2, MP10 are provided between the wiring layers 10-3a, 10-2b. The memory pillars MP7, MP15 are provided between the wiring layers 10-2b, 10-3b. The memory pillars MP3, MP11 are provided between the wiring layers 10-3b, 10-0c.

The memory pillar MP is a structure body in which the select transistors ST1, ST2, and the memory cell transistor MT are formed. A detailed structure of the memory pillar MP will be described later.

The memory pillars MP0 to MP3 are arranged along the Y-direction. The memory pillars MP8 to MP11 are arranged along the Y-direction at positions adjacent to the memory pillars MP0 to MP3 in the X-direction. In other words, the memory pillars MP0 to MP3 and the memory pillars MP8 to MP11 are arranged in parallel.

The memory pillars MP4 to MP7 and MP12 to MP15 are arranged along the Y-direction. The memory pillars MP4 to MP7 are located between the memory pillars MP0 to MP3 and the memory pillars MP8 to MP11 in the X-direction. The memory pillars MP12 to MP15 are arranged along the Y-direction at positions adjacent to the memory pillars MP4 to MP7 in the X-direction. In other words, the memory pillars MP4 to MP7 and the memory pillars MP12 to MP15 are arranged in parallel.

Two bit lines BL0, BL1 are provided above the memory pillars MP0 to MP3. The bit line BL0 is commonly connected to the memory pillars MP1, MP3. The bit line BL1 is commonly connected to the memory pillars MP0, MP2. Two bit lines BL2, BL3 are provided above the memory pillars MP4 to MP7. The bit line BL2 is commonly connected to the memory pillars MP5, MP7. The bit line BL3 is commonly connected to the memory pillars MP4, MP6.

Two bit lines BL4, BL5 are provided above the memory pillars MP8 to MP11. The bit line BL4 is commonly connected to the memory pillars MP9, MP11. The bit line BL5 are commonly connected to the memory pillars MP8, MP10. Two bit lines BL6, BL7 are provided above the memory pillars MP12 to MP15. The bit line BL6 is commonly connected to the memory pillars MP13, MP15. The bit line BL7 is commonly connected to the memory pillars MP12, MP14.

In the present embodiment, in the Y-direction, the positions of each of the memory pillars MP0 to MP3, MP8 to MP11 are shifted by ½ of a distance between the memory pillars MP with respect to the positions of each of the memory pillars MP4 to MP7, MP12 to MP15. The memory pillars MP0 to MP3, MP8 to MP11 are classified into a group GR0. The memory pillars MP4 to MP7, MP12 to MP15 are classified into a group GR1.

Although the details will be described later, the bit line BL0 connected to the memory pillars MP1, MP3 and the bit line BL4 connected to the memory pillars MP9, MP11 may be referred to as a first group GR1. The bit lines BL1 to BL3 connected to the memory pillars MP0, 2, 4 to 7 and the bit lines BL5 to BL7 connected to the memory pillars MP8, MP10, MP12 to MP15 may be referred to as a second group GR2.

The memory pillar MP is not provided in an area between the wiring layers 10-0a and 10-0c adjacent to each other with the slit SLT1 interposed therebetween. However, from the viewpoint of process stability, the area may be provided with a dummy memory pillar MP which is not connected to the BL.

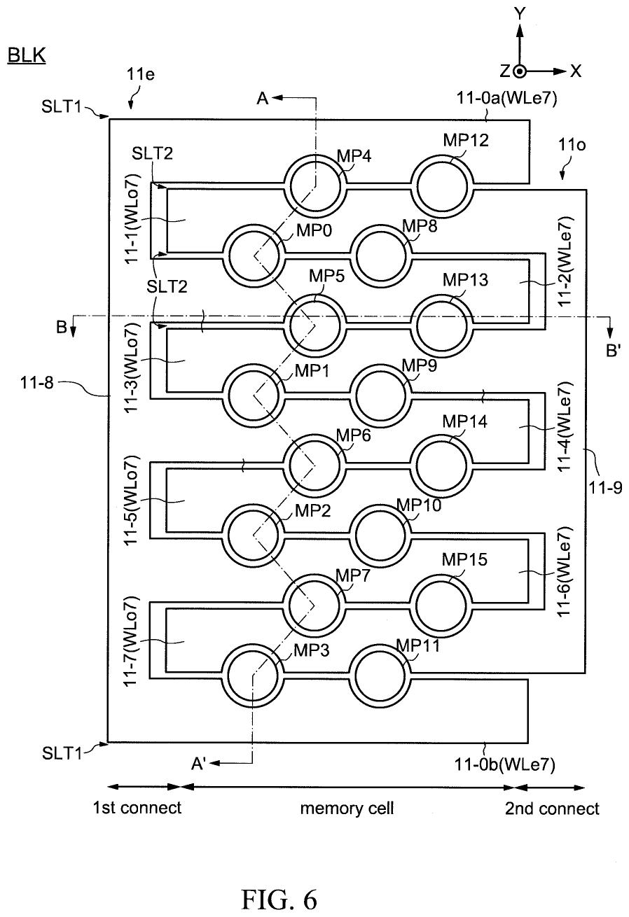

FIG. 6 shows a planar layout of the word lines WL in the X-Y plane, similar to FIG. 5. FIG. 6 corresponds to one block of the area of FIG. 5 and is a layout of wiring layers 11 provided lower layer than the wiring layer 10 described in FIG. 5.

As shown in FIG. 6, the nine wiring layers 11 (11-0a, 11-0b, 11-1 to 11-7) extending in the X-direction are arranged along the Y-direction. Each wiring layer 11-0a, 11-0b, 11-1 to 11-7 is provided in the lower layer of the wiring layers 10-0 to 10-7 via an insulation layer.

Each wiring layer 11 functions as a word line WL7. Other word lines WL0 to WL6 have the same configuration and function as the word line WL7. As shown in FIG. 6, the wiring layers 11-0a, 11-2, 11-4, 11-6, 11-0b functioning as the word line WLe7 have the longitudinal in the X-direction, respectively, are arranged side by side in the Y-direction. The wiring layers 11-0a, 11-2, 11-4, 11-6, 11-0b are connected by a first connecting section 11-8 (1st connect) having the longitudinal in the Y-direction. The first connect 11-8 is provided at the first end in the X-direction. The wiring layers 11-0a, 11-2, 11-4, 11-6, 11-0b are connected to the row decoder 30 via the first connecting section 11-8. The first connect 11-8 and the wiring layers 11-0a, 11-2, 11-4, 11-6, 11-0b may be collectively referred to as a wiring layer lie.

The Wiring layers 11-1, 11-3, 11-5, 11-7 functioning as the word line WLo7 have the longitudinal in the X-direction, respectively, and are arranged side by side in the Y-direction. These wiring layers 11-1, 11-3, 11-5, 11-7 are connected by a second connect 11-9 having the longitudinal in the Y-direction. The second connecting section 11-9 (2nd connect) is provided at the second end that is an end portion opposite to the first end of the first connecting section 11-8 in the X-direction. The wiring layers 11-1, 11-3, 11-5, 11-7 are connected to the row decoder 30 via the second connecting section 11-9. The second connecting section 11-9 and the wiring layers 11-1, 11-3, 11-5, 11-7 may be collectively referred to as a wiring layer 11o.

The memory cell section (memory cell) is provided between the first connecting section 11-8 and the second connecting section 11-9. A portion of the memory cell section facing the wiring layer 11e is referred to as a “first memory cell section”, and a portion of the memory cell section facing the wiring layer 11o may be referred to as a “second memory cell section”. In the memory cell section, the wiring layers 11 adjacent to each other in the Y-direction are separated by the slit SLT2 described with reference to FIG. 5. The wiring layers 11 between the blocks BLK adjacent to each other in the Y-direction are also separated by the slit SLT1 as described in FIG. 5. In the memory cell section, the memory pillars MP0 to MP15 are provided in the same manner as in FIG. 5.

The select gate line SGS and the word lines WL0 to WL6 have the same configuration as the word line WL7 of FIG. 6.

### <Cross-Sectional Structure of Memory Cell Array>

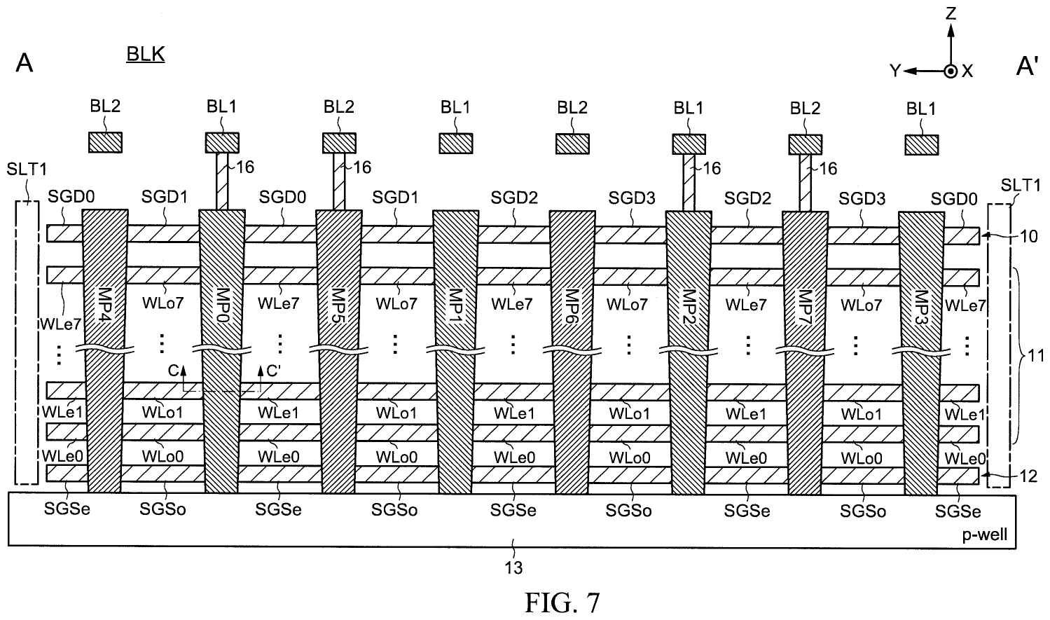

The cross-sectional structure of the memory cell array 21 will be described with reference to FIG. 7. FIG. 7 is a A-A′ cross-sectional view of the semiconductor storage device shown in FIG. 6.

As shown in FIG. 7, above a p-type well area (p-well) of a semiconductor substrate 13, a wiring layer 12 functioning as the select gate line SGS is provided. Above the wiring layer 12, eight wiring layers 11 functioning as the word lines WL0 to WL7 are stacked along the Z-direction. The planar layout of the wiring layers 11, 12 is similar to the layout shown in FIG. 6. Above the wiring layer 11, the wiring layer 10 functioning as the select gate line SGD is provided. The planar layout of the wiring layer 10 is the layout shown in FIG. 5.

The wiring layer 12 functions as the select gate line SGSo or the select gate line SGSe. The select gate lines SGSo, SGSe are alternately arranged in the Y-direction. The memory pillar MP is provided between the select gate lines SGSo, SGSe adjacent to each other in the Y-direction.

The wiring layer 11 functions as the word line WLo or the word line WLe. The word lines WLo and WLe are alternately arranged in the Y-direction. The memory pillar MP is provided between the word lines WLo, WLe adjacent to each other in the Y-direction. A memory cell described later is provided between the memory pillar MP and the word line WLo and between the memory pillar MP and the word line WLe.

The slit SLT1 is provided between the blocks BLK adjacent to each other in the Y-direction. As described above, the slit SLT1 is provided with an insulation layer. However, a contact plug or the like for supplying a voltage to an area provided in the semiconductor substrate 13 may be provided in the slit SLT1. For example, a contact plug or groove-shaped conductor for connecting the source of the select transistor ST2 to the source line may be provided in the slit SLT1.

The bit lines BL1, BL2 are provided on the memory pillar MP. A contact plug 16 for connecting each memory pillar MP and the bit line BL is provided between the memory pillar MP0 and the bit line BL1 and between the memory pillar MP2 and the bit line BL1. Similarly, the contact plug 16 for connecting each memory pillar MP and the bit line BL is provided between the memory pillar MP5 and the bit line BL2 and between the memory pillar MP7 and the bit line BL2. The other memory pillars MP are connected to the bit line BL1 or the bit line BL2 through the contact plug 16 in an area other than the cross section shown in FIG. 7.

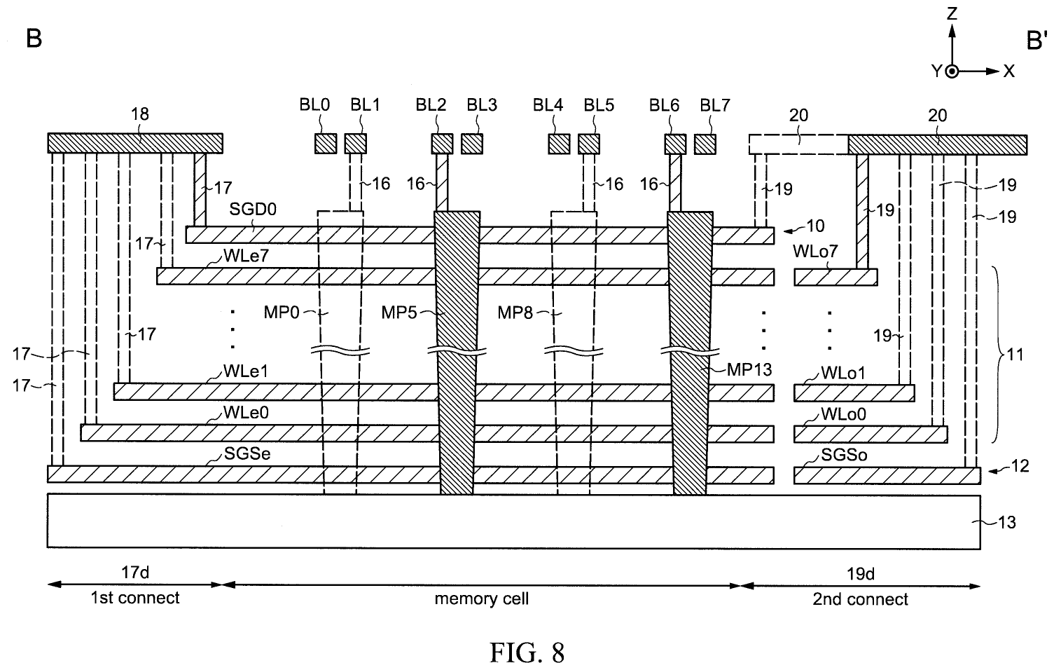

FIG. 8 is a B-B′ cross-sectional view of the semiconductor storage device shown in FIG. 6. As described in an explanation of FIG. 7, the wiring layers 12, 11, 10 are provided sequentially above the semiconductor substrate 13. In FIG. 8, the configuration existing in the depth direction of the B-B′ cross-sectional view is drawn by a dotted line.

In a first connecting section 17d (1st connect), the wiring layers 11, 12 are formed in a stepped shape. That is, when viewed in the X-Y plane, each end portion of the eight wiring layers 11 and the upper surface of the end portion of the wiring layer 12 are exposed in the first connecting section 17d. A contact plug 17 is provided in the wiring layers 11, 12 exposed at the first connecting section 17d. The contact plug 17 is connected to a metal wiring layer 18. The wiring layers 10 to 12 functioning as even select gate lines SGD0, SGD2, SGD4, SGD6, an even word line WLe, and an even select gate line SGSe, are electrically connected to the row decoder 30 via the metal wiring layer 18.

In a second connecting section 19d (2nd connect), similar to the above, the wiring layers 11, 12 are formed in a stepped shape. That is, when viewed in the X-Y plane, each end portion of the eight wiring layers 11 and the upper surface of the end portion of the wiring layer 12 are exposed in the second connecting section 19d. A contact plug 19 is provided in the wiring layers 11, 12 exposed at the second connecting section 19d. The contact plug 19 is connected to a metal wiring layer 20. The wiring layers 11, 12 functioning as odd select gate lines SGD1, SGD3, SGD5, SGD7, an odd word line WLo, and an odd select gate line SGSo are electrically connected to the row decoder 30 via the metal wiring layer 20.

The wiring layer 10 may be electrically connected to the row decoder 30 via the second connecting section 19d instead of the first connecting section 17d, may be electrically connected to the row decoder 30 via both the first connecting section 17d and the second connecting section 19d.

### <Structure of Memory Pillar and Memory Cell Transistor>

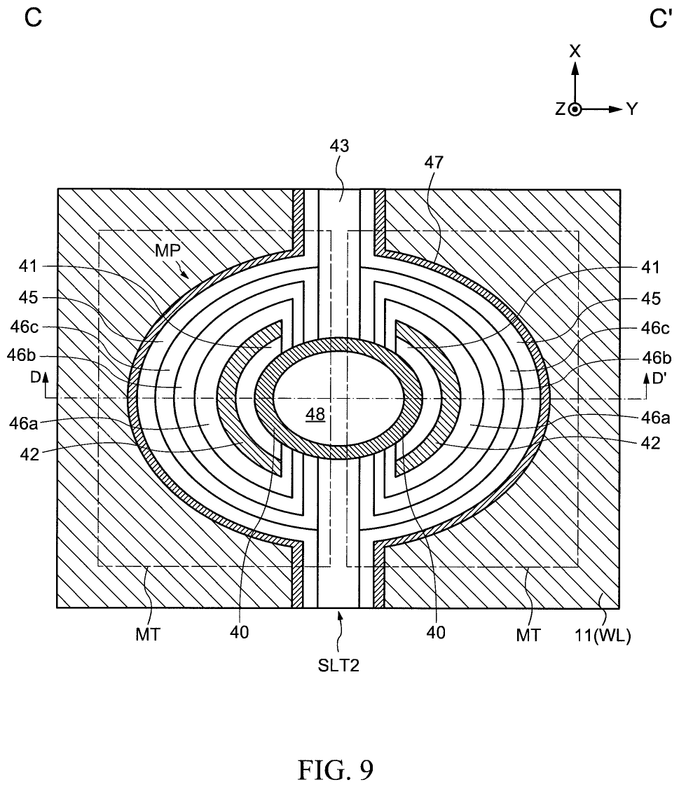

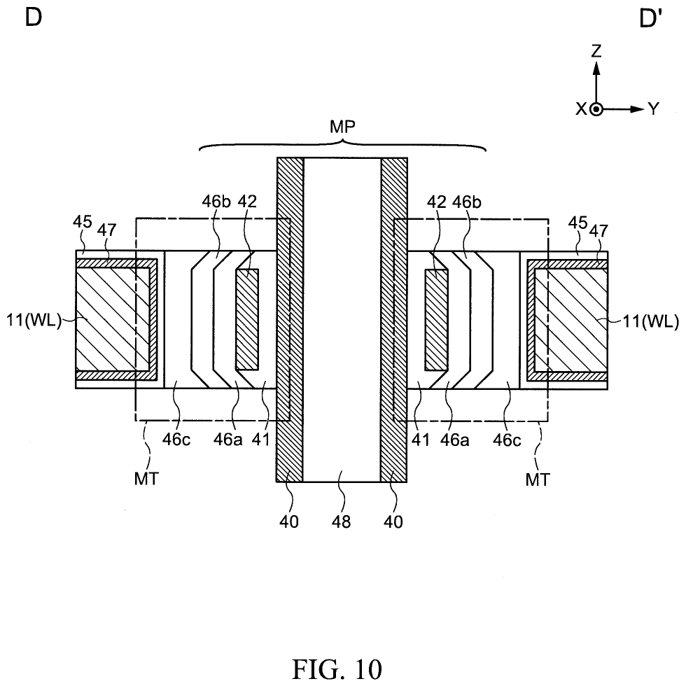

The structures of the memory pillar MP and the memory cell transistor MT will be described with reference to FIGS. 9 and 10.

### 1-4. FIRST EXAMPLE

The configurations of the memory pillar MP and the memory cell transistor MT according to a first example will be described with reference to FIGS. 9 and 10. FIG. 9 is a C-C′ cross-sectional view of the memory cell shown in FIG. 7. FIG. 10 is a D-D′ cross-sectional view of the memory cell shown in FIG. 9. In the first example, a floating gate type memory cell transistor MT is shown in which a conductive layer is used as the charge storage layer of the memory cell transistor MT.

As shown in FIGS. 9 and 10, the memory pillars MP include insulation layers 48, 43, a semiconductor layer 40, an insulation layer 41, a conductive layer 42, and insulation layers 46a to 46c provided along the Z-direction. The insulation layer 48 is, for example, a silicon oxide layer. The semiconductor layer 40 is provided to surround the periphery of the insulation layer 48. The semiconductor layer 40 is, for example, a polycrystalline silicon layer. The semiconductor layer 40 functions as a channel of the memory cell transistor MT. The semiconductor layer 40 is provided continuously between the two memory cell transistors MT included in one memory pillar MP and is not separated for each memory cell transistor MT.

As described above, the semiconductor layer 40 is continuous between the two memory cell transistors MT facing each other. Therefore, the two channels formed in the two memory cell transistors MT share a part of the memory pillar MP. Specifically, in FIG. 9, in the memory cell transistor MT on the left side and the memory cell transistor MT on the right side facing each other, the channel formed in the memory cell transistor MT on the left side and the channel formed in the memory cell transistor MT on the right side share a part of the memory pillar MP. The two channels share a part of the memory pillar MP means that the two channels are formed in the same memory pillar MP and that the two channels are partially overlapped. The above configuration may be referred to as that the two memory cell transistors MT share the channel or the two memory cell transistors MT face each other.

The insulation layer 41 is provided around the semiconductor layer 40 and functions as a gate insulation layer of each memory cell transistor MT. The insulation layer 41 is separated into two areas in the X-Y plane shown in FIG. 9. Each of the insulation layers 41 functions as the gate insulation layer of the two memory cell transistors MT included in one memory pillar MP. The insulation layer 41 is, for example, a stacked structure of the silicon oxide layer and the silicon nitride layer. The conductive layer 42 is provided around the insulation layer 41 and is separated into two areas along the Y-direction by the insulation layer 43. The conductive layer 42 is, for example, a polycrystalline silicon layer having conductivity. Each of the separated conductive layers 42 functions as the charge storage layer of the two memory cell transistors MT described above.

The insulation layer 43 is, for example, a silicon oxide layer. Around the conductive layer 42, the insulation layers 46a, 46b, 46c are provided sequentially. The insulation layers 46a, 46c are, for example, silicon oxide layers. The insulation layer 46b is, for example, a silicon nitride layer. The insulation layers function as block insulation layers of the memory cell transistor MT. The insulation layers 46a to 46b are also separated into two areas along the Y-direction. The insulation layer 43 is provided between the separated insulation layers 46a to 46b. The insulation layer 43 is embedded in the slit SLT2. The insulation layer 43 is, for example, a silicon oxide layer.

Around the memory pillar MP having the above-described configuration, an AlO layer 45 is provided, for example. Around the AlO layer 45, a barrier metal layer 47 (TiN layer or the like) is provided, for example. Around the barrier metal layer 47, the wiring layer 11 functioning as the word line WL is provided. The wiring layer 11 is, for example, tungsten.

According to the above configuration, two memory cell transistors MT are provided in one memory pillar MP along the Y-direction. The select transistors ST1 and ST2 also have the same configuration as described above. An insulation layer (not shown) is provided between the memory cell transistors adjacent to each other in the Z-direction. By the insulation layer and the insulation layers 43, 46, the conductive layer 42 is insulated for each individual memory cell transistor.

### 1-5. EXAMPLE 2

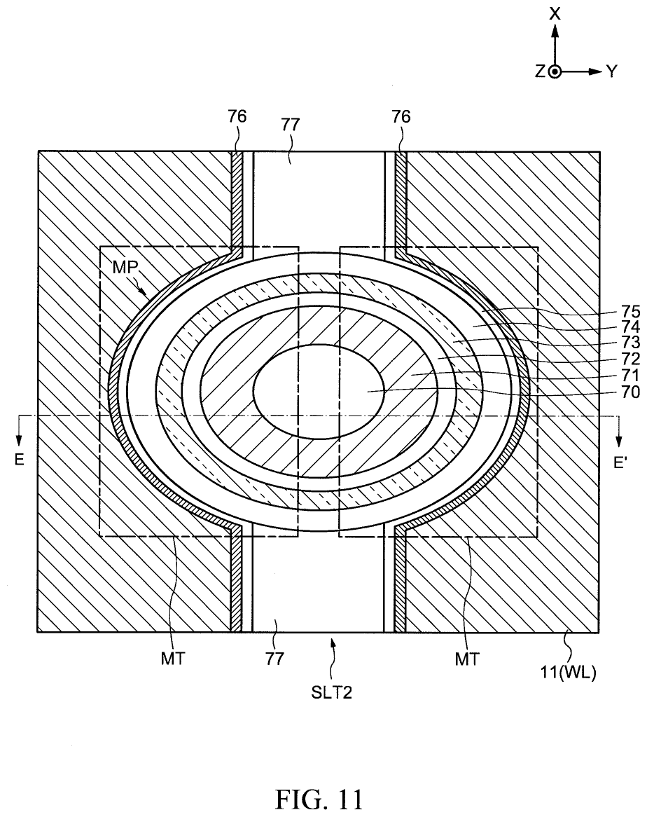

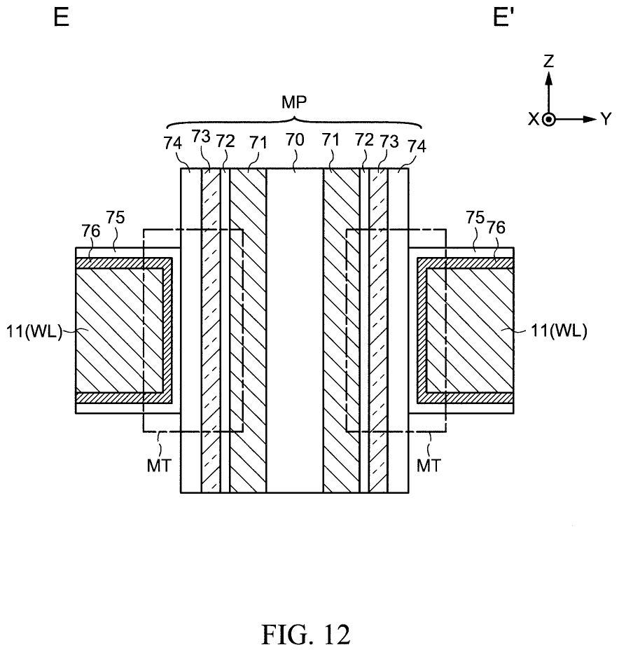

The configurations of the memory pillar MP and the memory cell transistor MT according to a second example will be described with reference to FIGS. 11 and 12. FIG. 11 is a modification of the memory cell shown in FIG. 9. FIG. 12 is an E-E′ cross-sectional view of the memory cell shown in FIG. 11. In the second example, a MONOS type memory cell transistor MT that an insulation layer is used in the charge storage layer of the memory cell transistor MT is shown.

As shown in FIGS. 11 and 12, the memory pillar MP includes an insulation layer 70, a semiconductor layer 71, and insulation layers 72 to 74 provided along the Z-direction. The insulation layer 70 is, for example, a silicon oxide layer. The semiconductor layer 71 is provided to surround the periphery of the insulation layer 70. The semiconductor layer 71 functions as the channel of the memory cell transistor MT. The semiconductor layer 71 is, for example, a polycrystalline silicon layer. The semiconductor layer 71 is continuously provided between the two memory cell transistors MT included in one memory pillar MP. Therefore, the channels formed in each of the two memory cell transistors MT share a part of the memory pillar MP.

The insulation layer 72 is provided to surround the semiconductor layer 71, and functions as the gate insulation layer of the memory cell transistor MT. The insulation layer 72 is, for example, a stacked structure of a silicon oxide layer and a silicon nitride layer. The insulation layer 73 is provided to surround the periphery of the semiconductor layer 71 and functions as the charge storage layer of the memory cell transistor MT. The insulation layer 73 is, for example, a silicon nitride layer. The insulation layer 74 is provided to surround the periphery of the insulation layer 73 and functions as the block insulation layer of the memory cell transistor MT. The insulation layer 74 is, for example, a silicon oxide layer. An insulation layer 77 is embedded in the slit SLT2 except for the memory pillar MP portion. The insulation layer 77 is, for example, a silicon oxide layer.

For example, around the memory pillar MP having the above-described configuration, an AlO layer 75 is provided. For example, around the AlO layer 75, a barrier metal layer 76 (TiN layer or the like) is provided. Around the barrier metal layer 76, the wiring layer 11 functioning as the word line WL is provided. The wiring layer 11 is, for example, tungsten.

According to the above configuration, two memory cell transistors MT are provided in one memory pillar MP along the Y-direction. The select transistors ST1 and ST2 also have the same configuration as described above.

### 1-6. EQUIVALENT CIRCUIT

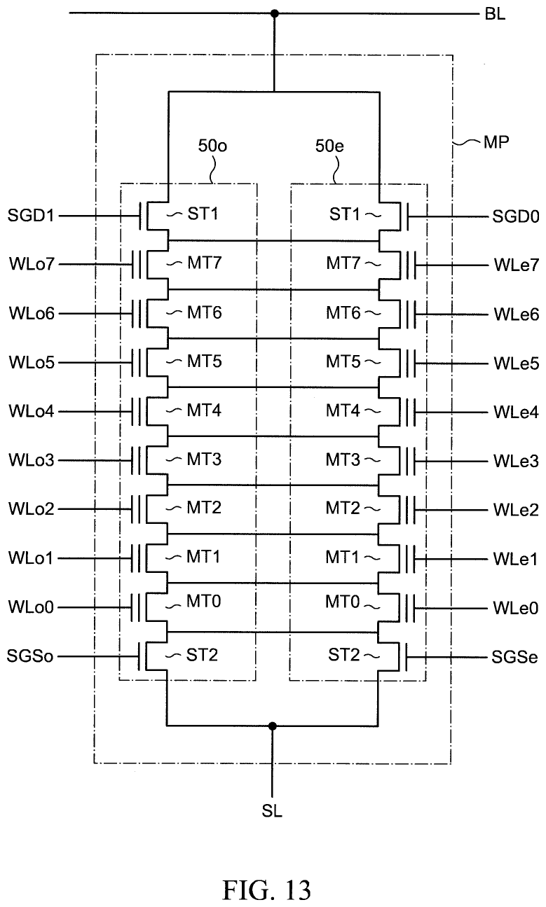

FIG. 13 is a diagram illustrating an equivalent circuit of the adjacent strings in the semiconductor storage device according to an embodiment. As shown in FIG. 13, the two NAND strings 50o, 50e are formed in one memory pillar MP. Each of the NAND strings 50o, 50e has the select transistor ST1, the memory cell transistors MT0 to MT7, and the select transistor ST2, connected in series.

The select transistor ST1 of the NAND string 50o is connected to the select gate line SGD1. The select transistor ST1 of the NAND string 50e is connected to the select gate line SGD0. The memory cell transistors MT0 to MT7 of the NAND string 50o are connected to the word lines WLo0 to WLo7, respectively. The memory cell transistors MT0 to MT7 of the NAND string 50e are connected to the word lines WLe0 to WLe7, respectively. Among the word lines WLo0 to WLo7, the word line WLo0 is the lowermost layer and the word line WLo7 is the uppermost layer. Among the word lines WLe0 to WLe7, the word line WLe0 is the lowermost layer and the word line WLe7 is the uppermost layer. The select transistor ST2 of the NAND string 50o is connected to the select gate line SGSo. The select transistor ST2 of the NAND string 50e is connected to the select gate line SGSe.

The sources of the select transistors ST1 facing each other are electrically connected. The drains of the select transistors ST1 facing each other are electrically connected. The sources of the each of memory cell transistors MT0 to 7 facing each other are electrically connected. The drains of the each of memory cell transistors MT0 to 7 facing each other are electrically connected. The sources of the select transistors ST2 facing each other are electrically connected. The drains of the select transistors ST2 facing each other are electrically connected. The electrical connection described above is due to the channels formed in the transistors facing each other share a part of the memory pillar MP.

The two NAND strings 50o, 50e in the same memory pillar MP are connected to the same bit line BL and the same source line SL.

### 1-7. THRESHOLD DISTRIBUTION OF MEMORY CELL TRANSISTOR

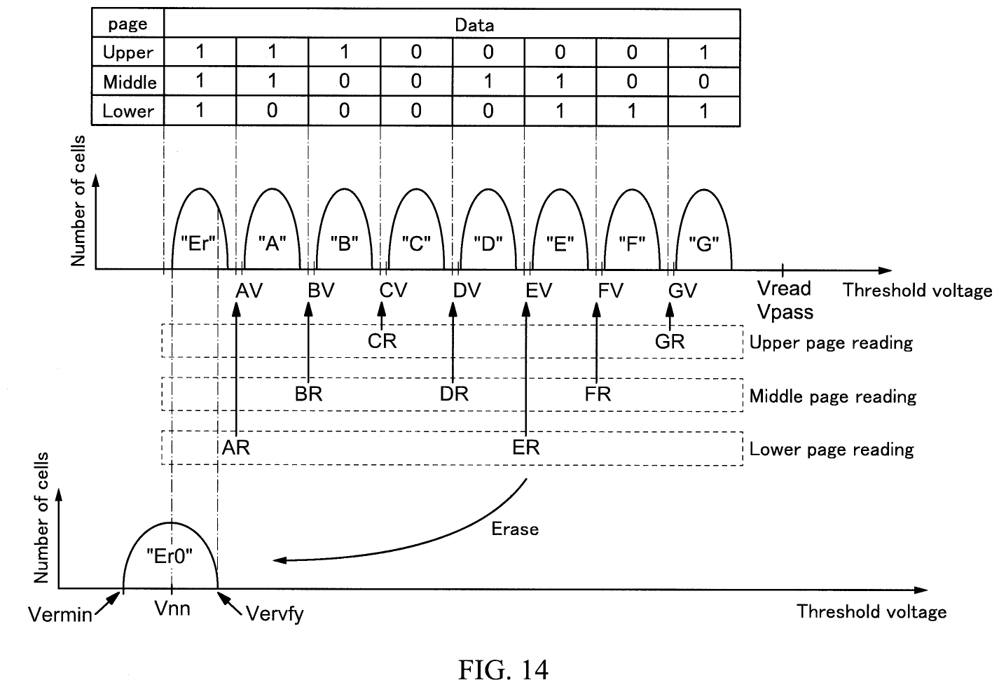

FIG. 14 is a diagram illustrating a threshold distribution of a transistor (memory cell transistor) used as the memory cell according to an embodiment. In FIG. 14, Triple Level Cell (TLC) is described as an example of the threshold distribution of the memory cell transistor, but Quad Level Cell (QLC), Multi Level Cell (MLC), and Single Level Cell (SLC) may be used in the memory system 1.

FIG. 14 shows an example of the threshold distribution, a data allocation, a read voltage, and a verify voltage of the memory cell transistor, respectively. The vertical axis of the threshold distribution shown in FIG. 14 corresponds to the number of memory cell transistors (Number of cells), and the horizontal axis corresponds to a threshold voltage Vth (Threshold voltage) of the memory cell transistor.

As shown in FIG. 14, in the TLC method, a plurality of memory cell transistors may form eight threshold distributions. The eight threshold distributions may be referred to as write levels. The write levels are referred to as “Er” level, “A” level, “B” level, “C” level, “D” level, “E” level, “F” level, and “G” level in order from the lower threshold voltage. For example, different three-bits data are allocated to these write levels, as described below. These 3-bits data are called a lower bit (Lower), a middle bit (Middle), and an upper bit (Upper).

A group of Lower bits held by the memory cell transistors connected to the same word line is referred to as a Lower page. A group of Middle bits held by the memory cell transistors is referred to as a Middle page. A group of Upper bits held by the memory cell transistors is referred to as an Upper page. The data write operation and read operation are performed in the above page units.
“Er” level: “111” data
“A” level: “110” data
“B” level: “100” data
“C” level: “000” data
“D” level: “010” data
“E” level: “011” data
“F” level: “001” data
“G” level: “101” data

The above data are presented in the order of Upper, Middle, Lower.

Between the adjacent threshold distributions, a verify voltage used in the write operation is set. Specifically, the verify voltages AV, BV, CV, DV, EV, FV, and GV are set corresponding to each of “A” level, “B” level, “C” level, “D” level, “E” level, “F” level, and “G” level.

For example, the verify voltage AV is set between the maximum threshold voltage in the “Er” level and the minimum threshold voltage in the “A” level. When the verify voltage AV is applied to the memory cell transistor, the memory cell transistor whose threshold voltage is included in the “Er” level is turned on, and the memory cell transistor whose threshold voltage is included in the “A” to “G” levels (threshold distributions whose threshold voltages are equal to or higher than the threshold voltage of the “A” level) is turned off.

Other verify voltages BV, CV, DV, EV, FV, and GV are also set in the same manner as the verify voltage AV. The verify voltage BV is set between the “A” level and the “B” level. The verify voltage CV is set between the “B” level and the “C” level. The verify voltage DV is set between the “C” level and the “D” level. The verify voltage EV is set between the “D” level and the “E” level. The verify voltage FV is set between the “E” level and the “F” level. The verify voltage GV is set between the “F” level and the “G” level.

For example, the verify voltage AV may be set to 0.8V, the verify voltage BV may be set to 1.6V, the verify voltage CV may be set to 2.4V, the verify voltage DV may be set to 3.1V, the verify voltage EV may be set to 3.8V, the verify voltage FV may be set to 4.6V, and the verify voltage GV may be set to 5.6V. However, these verify voltages AV to GV are not limited to the above voltage values. The verify voltages AV to GV may be set, for example, in the range of 0.0V to 7.0V, as appropriate, step by step.

The read voltages used in the respective read operations are set between the adjacent threshold distributions. For example, the read voltage AR is set between the maximum threshold voltage in the “Er” level and the minimum threshold voltage in the “A” level. The read voltage AR is a voltage for determining whether the threshold voltage of the memory cell transistor is included in the “Er” level or included in the “A” level or higher.

Other read voltages BR, CR, DR, ER, FR, and GR are also set between adjacent levels, as similar to the read voltage AR. For example, the read voltage BR is set between the “A” level and the “B” level. The read voltage CR is set between the “B” level and the “C” level. The read voltage DR is set between the “C” level and the “D” level. The read voltage ER is set between the “D” level and the “E” level. The read voltage FR is set between the “E” level and the “F” level. The read voltage GR is set between the “F” level and the “G” level.

A voltage Vread applied to a non-selected WL when the read operation is performed is set to a voltage value higher than the maximum threshold voltage in the highest threshold distribution (e.g., “G” level). The memory cell transistor whose gate is supplied with the Vread is turned on regardless of the stored data.

The verify voltages AV, BV, CV, DV, EV, FV, and GV are set to higher voltages than the read voltages AR, BR, CR, DR, ER, FR, and GR, respectively. In other words, the verify voltages AV to GV are set at the neighborhood of the minimum thresholds (hereinafter, sometimes referred to as the “lower tail of the threshold distribution”) in the threshold distribution of “A” level, “B” level, “C” level, “D” level, “E” level, “F” level, and “G” level, respectively.

When the above-described data allocation is applied, the data of one page of the lower bit (data of Lower page) in the read operation is determined by the read result using the read voltages AR and ER. The data of one page of the middle bit (data of Middle page) is determined by the read result using the read voltages BR, DR, and FR. The data of one page of the upper bit (data of Upper page) is determined by the read result using the read voltages CR and GR. As described above, since the data of the Lower page, Middle page, and Upper page are determined by the 2 times, 3 times, and 2 times of read operation, respectively, the allocation of this data is referred to as “2-3-2 code”.

Next, a threshold voltage distribution immediately after an erase operation is performed on the memory cell transistor MT on which the write operation has been performed will be described.

When the erase operation (Erase) is performed, all the memory cell transistors MT to be erased will be transited to “Er0” state. The threshold voltage of the memory cell transistor MT in the “Er0” state is less than a voltage Vervfy and equal to or higher than a voltage Vermin. The voltage Vervfy is a voltage equal to or lower than the voltage AV and higher than a voltage Vnn (e.g., 0V). The voltage Vermin is the lowest threshold voltage that the memory cell transistor MT can take by the erase operation and is a voltage lower than the voltage Vnn. For example, the voltage Vnn is a negative voltage (<0V) and is the lowest voltage of the voltages that can be generated in the semiconductor storage devices 5 to 8. The “Er0” state includes the memory cell transistor MT having the threshold voltage less than the voltage Vnn. On the other hand, the “Er” state does not include the memory cell transistor MT having the threshold voltage less than the voltage Vnn. In the above point, the “Er0” state and the “Er” state are different.

The memory cell transistor MT belonging to the “Er0” state does not belong to any state of the “A” state to the “G” state because the threshold voltage is controlled to be equal to or lower than the voltage Vervfy (≤VA). On the other hand, since the memory cell transistor MT has the threshold voltage lower than the voltage Vnn, the memory cell transistor MT can be turned on even when the lowest voltage among the voltages that can be generated in the semiconductor storage devices 5 to 8 is applied to the word line WL.

Hereinafter, the memory cell transistor MT whose threshold voltage is lower than the voltage Vnn is referred to as an “over-erased cell.” The threshold voltage of the over-erased cell is lower than the lowest voltage supplied at the read operation. That is, since the over-erased cell cannot be controlled to the off-state by applying a voltage to the word line WL, it may cause erroneous writing and erroneous reading. Therefore, it is desirable to suppress the number of the over-erased cell by performing the write operation on the over-erased cell. In the following description, the write operation performed to reduce the number of the over-erased cell is called an “over-erased cell write operation” (EP operation) or an “initial write operation” in distinction from a normal write operation.

### 1-8. READ OPERATION

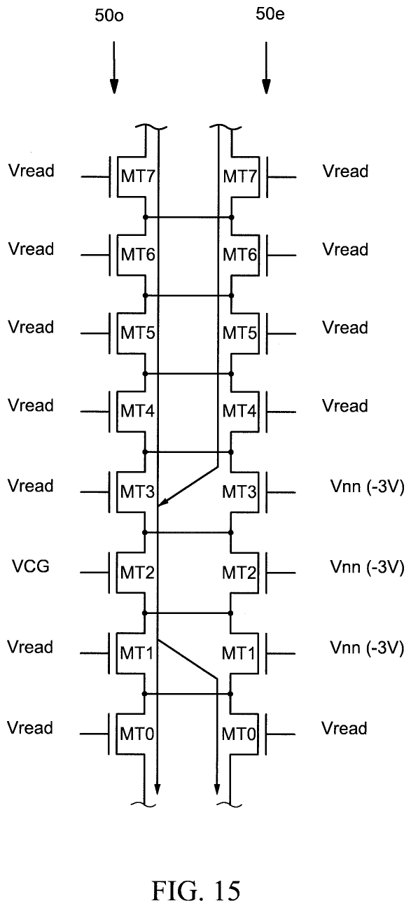

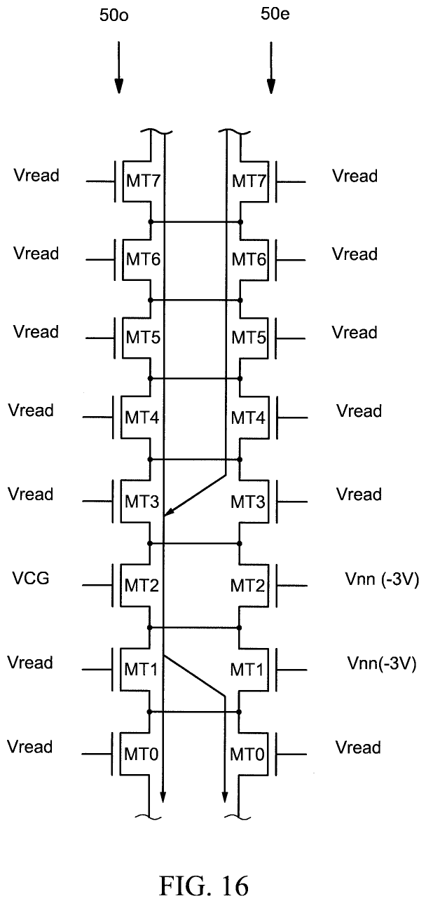

The read operation will be described with reference to FIGS. 15 and 16. As shown in FIG. 13, since the channels of the memory cell transistors MT facing each other share a part of the memory pillar MP, the sources and drains of the memory cell transistors MT facing each other are electrically connected. For example, as shown in FIG. 15, when the read operation is performed on the memory cell transistor MT2 of the NAND string 50o, at least the memory cell transistor MT2 of the NAND string 50e needs to be forcibly turned off.

Ideally, only the memory cell transistor MT facing the memory cell transistor MT that performs the read operation should be forcibly turned off in order to avoid the erroneous writing and erroneous reading. However, when the gate length of the memory cell transistor is short, the cut-off property of a single memory cell transistor MT may not be sufficiently able to eliminate the effect of the memory cell transistor MT of NAND string 50e. In that case, not only the facing memory cell transistor MT (the memory cell transistor MT2 of the NAND string 50e) but also the memory cell transistors MT located on both or one of the upper and lower thereof forcibly turned off so that can supplement the cut-off property. When the memory cell transistors MT facing each other and the memory cell transistors MT located above and below the memory cell transistors MT are forcibly turned off, the memory cell transistor MT belonging to word lines arranged in the three layers are turned off. Therefore, this operation is referred to as a “three-layers cut-off”. On the state hand, when the memory cell transistors MT facing each other and the memory cell transistor MT located above or below the memory cell transistor MT is forcibly turned off, the memory cell transistor MT belonging to word lines arranged in the two layers are turned off. Therefore, this operation is referred to as a “two-layers cut-off”.

FIG. 15 shows the three-layers cut-off read operation. The gate of the object cell transistor MT2 of the NAND string 50o to be read is supplied with a voltage VCG for reading data stored in the memory cell transistor MT. The gates of the memory cell transistors MT0 to MT1, MT3 to MT7 of the NAND string 50o are supplied with the Vread that forcibly turns on each memory cell transistor MT. The gates of the memory cell transistors MT1 to MT3 of the NAND string 50e are supplied with the Vnn (e.g., “−3V”) that forcibly turns off each memory cell transistor MT. The gates of the memory cell transistors MT0, MT4 to MT7 of the NAND string 50e are supplied with the Vread. That is, as described above, in the three-layers cut-off read operation, the memory cell transistor MT facing the memory cell transistor MT to be read and the memory cell transistors MT provided in the upper and lower layers thereof are forcibly turned off.

FIG. 16 shows a two-layers cut-off read operation. In the two-layers cut-off, unlike the above-described three-layers cut-off, the Vnn is supplied to the gates of the memory cell transistors MT1 to MT2 of the NAND string 50e, and the Vread is supplied to the gates of the other memory cell transistors MT0, MT3 to MT7 of the NAND string 50e. In other words, in the two-layers cut-off read operation, the memory cell transistor MT2 facing the memory cell transistor MT to be read and the memory cell transistor MT1 provided in the lower layer thereof are forcibly turned off. Unlike the example of FIG. 16, the memory cell transistor MT3 provided in the upper layer of the memory cell transistor MT2 facing the memory cell transistor MT may be forcibly turned off.

### 1-9. VERIFY OPERATION

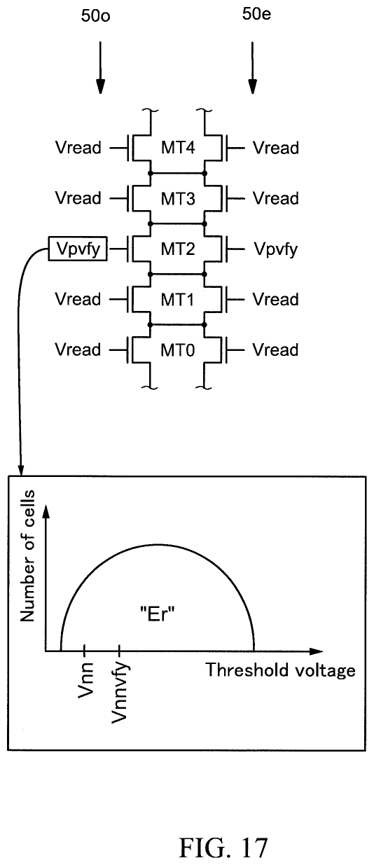

The verify operation performed before the write operation will be described with reference to FIG. 17. As described above, for example, when the memory cell transistor MT2 of the NAND string 50o is an over-erased cell in the memory cell transistors MT facing each other as in the present embodiment, even if the verify operation is performed on the memory cell transistor MT2 of the NAND string 50e, current flows through the memory cell transistor MT2 of the NAND string 50o. Therefore, among the memory cell transistors MT facing each other, it is difficult to determine which memory cell transistor MT is the over-erased cell. Therefore, in the memory cell transistor MT as in the present embodiment, as shown in FIG. 17, the verify operation is collectively performed on the memory cell transistors MT facing each other. Specifically, a verify voltage Vpvfy is supplied to the memory cell transistors MT2 on which the verify operation is performed, and the voltage Vread is supplied to the other memory cell transistors MT0, MT1, MT3, MT4.

### 1-10. OVER-ERASED CELL WRITE OPERATION

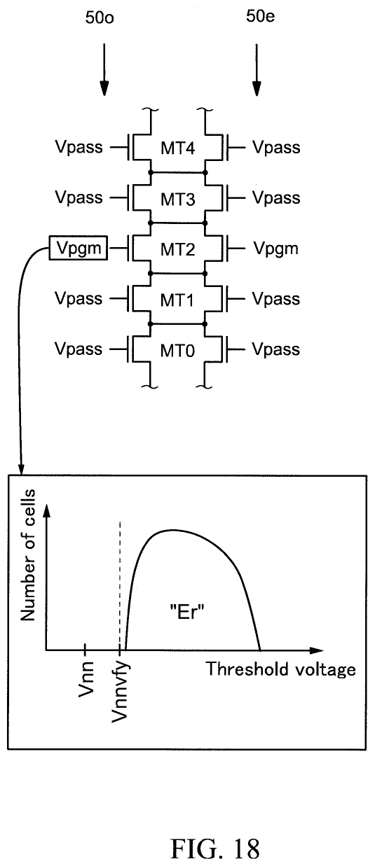

The over-erased cell write operation will be described with reference to FIG. 18. When the over-erased cell is detected in the above-described verify operation, the over-erased cell write operation (EP operation) is performed on both of the memory cell transistors MT facing each other. Specifically, an over-erased cell write voltage Vpgm is supplied to the memory cell transistor MT on which the over-erased cell write operation is performed, and a voltage Vpass is supplied to the other memory cell transistors MT. The over-erased cell write operation is a write operation that raises the threshold voltage only for a pair of memory cell transistors MT determined to be the over-erased cell. The over-erased cell write operation raises the threshold voltage of the memory cell transistor MT having a threshold voltage lower than the voltage Vnn among the threshold voltage distribution in the “Er” state shown in FIG. 17, for example. Consequently, the threshold voltage distribution is all higher than a voltage Vnnvfy as shown in FIG. 18.

### 1-11. WRITE OPERATION

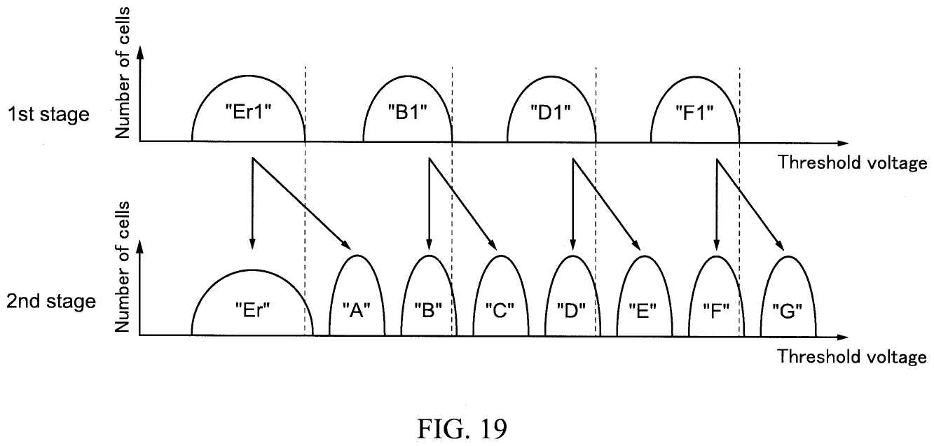

The write operation will be described with reference to FIGS. 19 to 29. In this embodiment, the write operation for one memory cell is realized by a plurality times of write operation. Such a write operation is referred to as a multi-stages write operation. The write operations are different depending on the number of stages of the write operation. Similarly, the write operations are different depending on the number of layers of the cut-off. In the following description, a two-stages write operation and a three-stages write operation will be described as the multi-stages write operation. For each write operation, the two-layers cut-off case and the three-layers cut-off case will be described.

### [1-11-1. Two-Stages Write Operation]

FIG. 19 is a diagram illustrating a two-stages write operation in the semiconductor storage device according to an embodiment. As shown in FIG. 19, the two-stages write operation includes a first stage write operation and a second stage write operation. In the first stage write operation, “Er1” level, “B1” level, “D1” level, and “F1” level are formed. In the second stage write operation after the first stage write operation, “Er” level to “G” level are formed.

The width of the threshold voltage distribution of the “B1” level, the “D1” level, and the “F1” level after the first stage write operation is larger than the width of the threshold voltage distribution of the “B” level, the “D” level, and the “F” level after the second stage write operation, respectively. The number of write levels (4) after the first stage write operation is smaller than the number of write levels (8) after the second stage write operation. The width of the threshold voltage distribution of the “Er” level after the second stage write operation is larger than the width of the threshold voltage distribution of the “Er1” level after the first stage write operation due to an unintentional increase in the threshold voltage caused by an interference effect and an effect of the program disturbance.

In the two-stages write operation, a rough write operation is performed by the first stage write operation, and a detailed write operation is performed by the second stage write operation. Specifically, when the final write level (the write level after the second stage write operation) is the “Er” level or the “A” level, after being written to the “Er1” level by the first stage write operation, it is written to the “Er” level or the “A” level by the second stage write operation.

Similar to the above, after being written to the “B1” level by the first stage write operation, it is written to the “B” level or the “C” level by the second stage write operation. Similarly, after being written to the “D1” level by the first stage write operation, it is written to the “D” level or the “E” level by the second stage write operation. Similarly, after being written to the “F1” level by the first stage write operation, it is written to the “F” level or the “G” level by the second stage write operation.

The maximum threshold voltage (hereinafter, sometimes referred to as the “upper tail of the threshold distribution”) of the threshold distribution at the smallest level among the plurality of levels after the second stage write operation separated from one level after the first stage write operation is located at a higher voltage side than the upper tail of the threshold distribution at the level before separating (the level after the first stage write operation). Specifically, the upper tail of the threshold distribution at the “B” level is located at a higher voltage side than the upper tail of the threshold distribution at the “B1” level. Since the write operation in the respective stages can only raise the threshold voltage, the write operation as described above is performed.

In the memory cell transistor MT according to the present embodiment, the threshold voltage of the written memory cell transistor MT (target memory cell transistor MT) varies according to the write operation of the other memory cell transistors MT performed after the write operation of the memory cell transistor MT. In this way, the threshold voltage of the target memory cell transistor MT varies with the write operation of the other memory cell transistor MT, and it is sometimes referred to as interference occurs.

By dividing the write operation into a plurality of stages, the effect of the interference caused by the write operation on the other memory cell transistors MT can be reduced.

### [1-11-2. Three-Stages Write Operation]

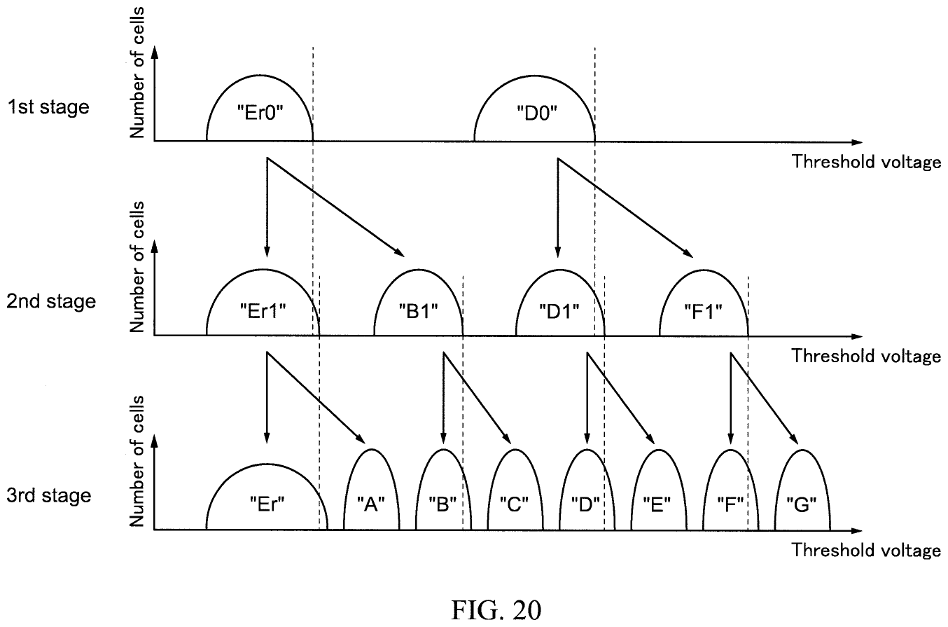

FIG. 20 is a diagram illustrating a three-stages write operation in the semiconductor storage device according to an embodiment. As shown in FIG. 20, the three-stages write operation includes a first stage write operation, a second-stage write operation, and a third-stage write operation. In the first stage write operation, the “Er0” level and the “D0” level are formed. In the second stage write operation after the first stage write operation, “Er1” level, “B1” level, “D1” level, and “F1” level are formed. In the third stage write operation after the second stage write operation, the “Er” level to the “G” level are formed. Since the second stage and the third stage in FIG. 20 are the same as the first stage and the second stage in FIG. 19, respectively, detailed description thereof is omitted.

The width of the threshold voltage distribution of the “D0” level after the first stage write operation is larger than the width of the threshold voltage distribution of the “D1” level after the second stage write operation. The number of write levels (2) after the first stage write operation is smaller than the number of write levels (4) after the second stage write operation. Similar to the above, the width of the threshold voltage distribution of the “Er1” level after the second stage write operation is larger than the width of the threshold voltage distribution of the “Er0” level after the first stage write operation, and the width of the threshold voltage distribution of the “Er” level after the third stage write operation is larger than the width of the threshold voltage distribution of the “Er1” level after the second stage write operation.

In the three-stages write operation, the first stage write operation performs a rougher write operation than the second stage write operation. Specifically, when the write level after the second stage write operation is the “Er1” level or the “B1” level, after being written to the “Er0” level by the first stage write operation, it is written to the “Er1” level or the “B1” level by the second stage write operation. Similar to the above, after being written to the “D0” level by the first stage write operation, it is written to the “D1” level and the “F1” level by the second stage write operation.

Similar to the above, the upper tail of the threshold distribution at the smallest level among the plurality of levels after the second stage write operation separated from one level after the first stage write operation is located at a higher voltage side than the upper tail of the threshold distribution at the level before separating (the level after the first stage write operation). Specifically, the upper tail of the threshold distribution at the “D1” level is located at a higher voltage side than the upper tail of the threshold distribution at the “D0” level. Similarly, the upper tail of the threshold distribution at the smallest level among the plurality of levels after the third stage write operation separated from one level after the second stage write operation is located at a higher voltage side than the upper tail of the threshold distribution at the level before separating (the level after the second stage write operation). Specifically, the upper tail of the threshold distribution at the “B” level is located at a higher voltage side than the upper tail of the threshold distribution at the “B1” level.

Since the write operation is performed in a plurality of stages, the effect of the write operation on the other memory cell transistors MT is reduced.

The above-described multi-stages write operation is merely an example, and the present embodiment can be applied to various other multi-stages write operation.

[1-11-3. Write Operation to Word Lines Arranged with the Same Layer]

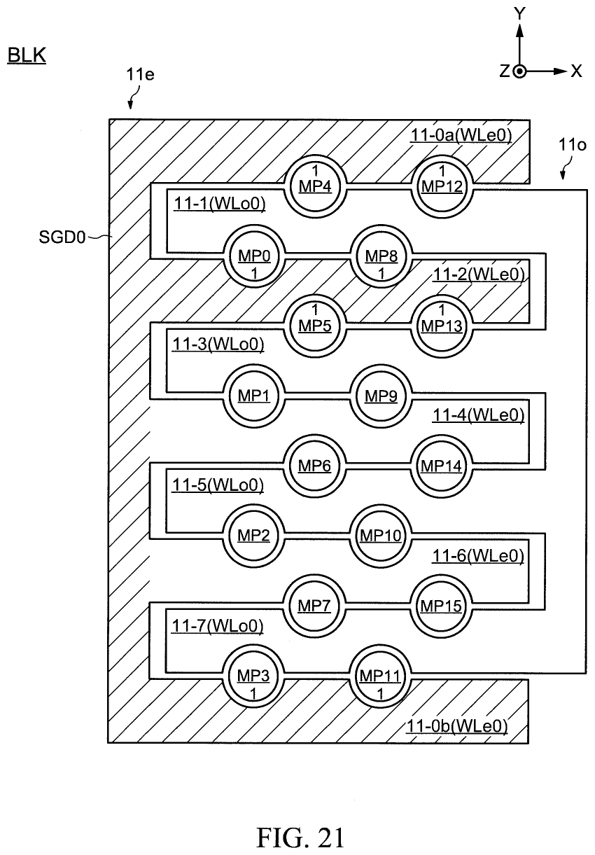

With reference to FIGS. 5 and 21 to 24, the write operation to the memory cell transistor MT in the block BLK is explained. FIGS. 21 to 24 are diagrams illustrating the write operation referring to the layouts of the word lines and memory pillars of the semiconductor storage device according to an embodiment. In FIGS. 14 to 17, the memory pillars MP (MP0 to MP15) and the word lines WL (the word lines WLe0, WLo0 which are the lowermost layer of the word lines) are shown. The memory cell transistor MT is provided in an area where the memory pillar MP and word line WL adjacent to each other.

When the write operation is performed, one of the select gate lines SGD0 to SGD3 shown in FIG. 5 is selected. The write operation is performed on the memory cell transistor MT belonging to the same NAND string 50o or 50e as the select transistor ST1 corresponding to the selected select gate line.

One wiring layer of 10-0 to 10-3 corresponding to each select gate line is supplied with a voltage that the select transistor ST1 turns on or off depending on the voltage supplied to the bit line BL.

Among the word lines WL0 to 7, a voltage for performing the write operation to the memory cell transistor MT is supplied to the wiring layer 11e or 11o corresponding to the memory cell transistor MT that is the target of the write operation. For example, the voltage for performing the write operation is a voltage for injecting electrons from the semiconductor layer 71 into the insulation layer 73. The semiconductor layer 71 functions as the channel. The insulation layer 73 functions as the charge storage layer.

When the select gate line SGD0 (the wiring layer 10-0) is selected and a voltage for performing the write operation to the lowermost word line WLe0 is supplied, the write operation is performed on the memory cell transistor MT located in the lowermost layer of the NAND string 50e in the memory pillars MP0, MP3, MP4, MP5, MP8, MP11, MP12, MP13.

When the select gate line SGD1 (the wiring layer 10-1) is selected and the voltage for performing the write operation to the lowermost word line WLo0 is supplied, the write operation is performed on the memory cell transistor MT located in the lowermost layer of the NAND string 50o in the memory pillars MP0, MP1, MP4, MP5, MP8, MP9, MP12, MP13.

When the select gate line SGD2 (the wiring layer 10-2) is selected and the voltage for performing the write operation to the lowermost word line WLe0 is supplied, the write operation is performed on the memory cell transistor MT located in the lowermost layer of the NAND string 50e in the memory pillars MP1, MP2, MP6, MP7, MP9, MP10, MP14, MP15.

When the select gate line SGD3 (the wiring layer 10-3) is selected and the voltage for performing the write operation to the lowermost word line WLo0 is supplied, the write operation is performed on the memory cell transistor MT located in the lowermost layer of the NAND string 50o in the memory pillars MP2, MP3, MP6, MP7, MP10, MP11, MP14, MP15.

In the block BLK, a group of the memory cell transistors MT in which are the target of the simultaneous write operation may be referred to as a “page”.

The word line WLe provided in the wiring layer 11e may be referred to as a “first word line”. The word line WLo provided in the wiring layer 11o may be referred to as a “second word line”. The wiring layer provided in the first word line and the second word line may be referred to as a “first layer”. The first word line and the second word line are controlled independently of each other. The memory pillar MP is sandwiched by the word line WLe (the first word line) and the word line WLo (the second word line). Among the memory cell transistors MT provided in the memory pillar MP, the memory cell transistor facing the word line WLe (the first word line) is referred to as the “first memory cell” and the memory cell transistor facing the word line WLo (the second word line) is referred to as the “second memory cell”. The plurality of memory pillars MP are arranged in the X-direction and the Y-direction.

The word line WLe provided in the wiring layer 11e corresponding to the “second layer” adjacent to the “first layer” in the vertical direction may be referred to as the “third word line”. The word line WLo provided in the wiring layer 11o corresponding to the “second layer” may be referred to as the “fourth word line”. The word line WLe provided in the wiring layer 11e corresponding to the “third layer” adjacent to the “second layer” in the vertical direction may be referred to as the “fifth word line”. The word line WLo provided in the wiring layer 11o corresponding to the “third layer” may be referred to as the “sixth word line”. The word line WLe provided in the wiring layer 11e corresponding to a “fourth layer” adjacent to the “third layer” in the vertical direction may be referred to as a “seventh word line”. The word line WLo provided in the wiring layer 11o corresponding to the “fourth layer” may be referred to as an “eighth word line”. The word line WLe provided in the wiring layer 11e corresponding to a “fifth layer” adjacent to the “fourth layer” in the vertical direction may be referred to as a “ninth word line”. The word line WLo provided in the wiring layer 11o corresponding to the “fifth layer” may be referred to as a “tenth word line”.

The third word line and the fourth word line are controlled independently from each other. The fifth word line and the sixth word line are controlled independently from each other. The seventh word line and the eighth word line are controlled independently from each other. The ninth word line and the tenth word line are controlled independently from each other. Each of the memory pillars MP is sandwiched between the word line WLe (third word line) and the word line WLo (fourth word line), the word line WLe (fifth word line) and the word line WLo (sixth word line), the word line WLe (seventh word line) and the word line WLo (eighth word line), and the word line WLe (ninth word line) and the word line WLo (tenth word line).

Among the memory cell transistors MT provided in the memory pillar MP, the memory cell transistor facing the third word line is referred to as the “third memory cell”. The memory cell transistor facing the fourth word line is referred to as the “fourth memory cell”. The memory cell transistor facing the fifth word line is referred to as the “fifth memory cell”. The memory cell transistor facing the sixth word line is referred to as the “sixth memory cell”. The memory cell transistor facing the seventh word line is referred to as a “seventh memory cell”. The memory cell transistor facing the eighth word line is referred to as an “eighth memory cell”. The memory cell transistor facing the ninth word line is referred to as a “ninth memory cell”. The memory cell transistor facing the tenth word line is referred to as a “tenth memory cell”.

Contrary to this embodiment, when the write operation is performed on the memory cell transistors MT facing the word lines WLe after the write operation is performed on the memory cell transistor MT facing the word lines WLo, the word lines WLo in the first, second, third, fourth, and fifth layers are referred to as the first word line, the third word line, the fifth word line, the seventh word line, and the ninth word line, respectively, and the word lines WLe in the first, second, third, fourth, and fifth layers are referred to as the second word line, the fourth word line, the sixth word line, the eighth word line, and the tenth word line, respectively. Similarly, the memory cell transistors MT facing the word lines WLo in the first, second, third, fourth, and fifth layers are referred to as the first memory cell, the third memory cell, the fifth memory cell, the seventh memory cell, and the ninth memory cell, respectively, and the memory cell transistors MT facing the word lines WLe in the first, second, third, fourth, and fifth layers are referred to as the second memory cell, the fourth memory cell, the sixth memory cell, the eighth memory cell, and the tenth memory cell, respectively. That is, in the two memory cell transistors MT facing each other, the memory cell transistor MT in which the write operation is performed first is referred to as an odd-numbered memory cell, and the memory cell transistor MT in which the write operation is performed later is referred to as an even-numbered memory cell.

Although the details will be described later, in the present embodiment, the write operation is performed by selecting in the order of the select gate lines SGD0→SGD2→SGD1→SGD3. In other words, in a first write operation, the write operation is performed on the first memory cell, the third memory cell, the fifth memory cell, the seventh memory cell and the ninth memory cell facing the wiring layer 11e (11-0a, 11-0b, 11-2, 11-4, 11-6) that functions as the word line WLe (the first word line, third word line, fifth word line, seventh word line and ninth word line) among the plurality of word lines 11 (11-0a, 11-0b, 11-1 to 11-7). In a second write operation after the first write operation, the write operation is performed on the second memory cell, the fourth memory cell, the sixth memory cell, the eighth memory cell and the tenth memory cell facing the wiring layer 110 (11-1, 11-3, 11-5, 11-7) that functions as the word line WLo (the second word line, the fourth word line, the sixth word line, the eighth word line and the tenth word line).

Referring to FIG. 21, as the first write operation to the memory cell transistor MT facing the lowermost word line WLe0 or WLo0, a case that the write operation is performed on the memory cell transistor MT belonging to the NAND string 50e selected by the select gate line SGD0 shown in FIG. 5 will be described. When the select gate line SGD0 is selected, depending on the voltage supplied to the bit line, the select transistor ST1 facing the wiring layers 10-0a, 10-0b, 10-0c shown in FIG. 5 is turned on or turned off depending on the voltage supplied to the bit line. In FIG. 21, an area (a hatching area) of the wiring layer 11e indicated by the hatching of the diagonal line corresponds to an area where the wiring layers 10-0a, 10-0b, 10-0c in FIG. 5 are arranged. That is, when the select gate line SGD0 is selected, the write operation is performed on the memory cell transistor MT facing the wiring layer 11e of the hatching area in FIG. 21.

As shown in FIG. 21, when the select gate line SGD0 (see FIG. 5) is selected, the write operation is performed on the memory cell transistor MT provided on the word line WLe0 side of each of the memory pillars MP0, MP3, MP4, MP5, MP8, MP11, MP12, MP13. In FIG. 21, “1” is indicated at a position corresponding to the memory cell transistor MT to which data has been written by the write operation (the first write operation).

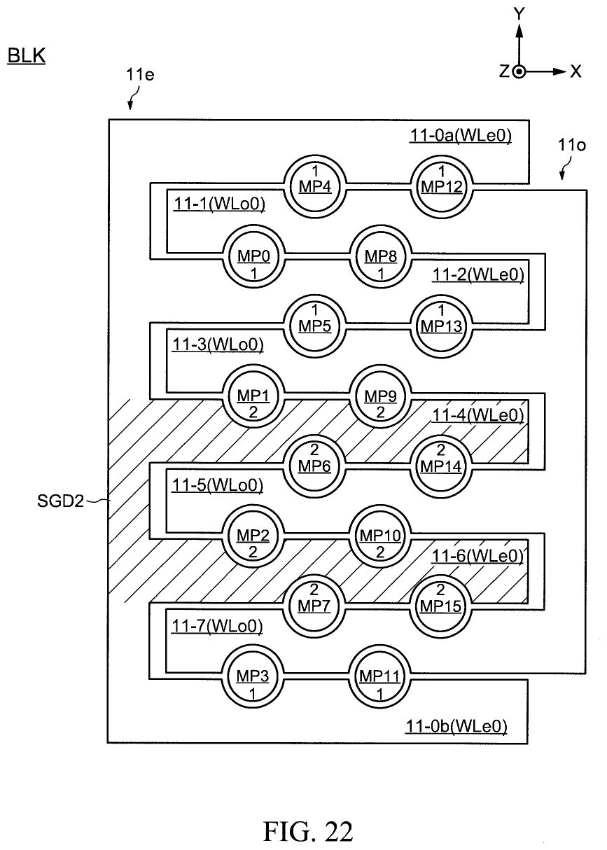

Referring to FIG. 22, the second write operation performed following the first write operation described above is described. The second write operation is a previous write operation to the memory cell transistor MT corresponding to the lowermost word line WLe0 or WLo0. In the second write operation, the write operation is performed on the memory cell transistor MT belonging to the NAND string 50e selected by the select gate line SGD2 shown in FIG. 5. When the select gate line SGD2 is selected, depending on the voltage supplied to the bit line, the select transistor ST1 facing the wiring layers 10-2a, 10-2b shown in FIG. 5 is turned on or turned off depending on the voltage supplied to the bit line. In FIG. 22, the hatching area of the wiring layer 11e corresponds to the area where the wiring layers 10-2a, 10-2b shown in FIG. 5 are arranged. That is, when the select gate line SGD2 is selected, the write operation is performed on the memory cell transistor MT facing the wiring layer 11e of the hatching area in FIG. 22.

As shown in FIG. 22, when the select gate line SGD2 (see FIG. 5) is selected, the write operation is performed on the memory cell transistor MT provided on the word line WLe0 side of each of the memory pillars MP1, MP2, MP6, MP7, MP9, MP10, MP14, MP15. In FIG. 22, “2” is indicated at a position corresponding to the memory cell transistor MT to which data has been written by the write operation (the second write operation).

By the write operation shown in FIGS. 21 and 22, the write operation to all the memory cell transistors MT facing the word line WLe0 formed in all the memory pillars MP0 to MP15 sandwiched between the word lines WLe0 and WLo0 is completed. In this state, the memory cell transistor MT formed in the memory pillars MP0 to MP15 and facing the word line WLo0 has not yet been performed to the write operation.

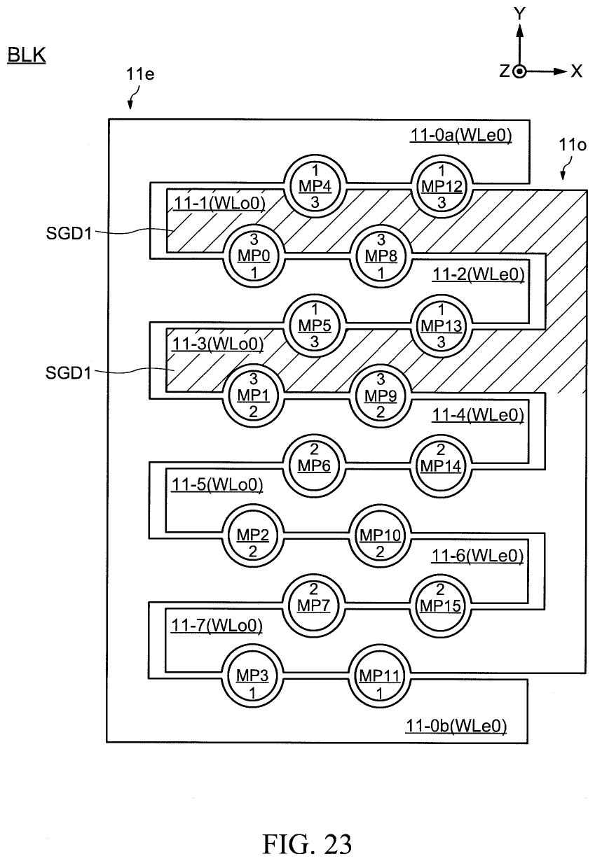

Referring to FIG. 23, a third write operation performed following the first and second write operations is described. The third write operation is a write operation to the memory cell transistor MT corresponding to the lowermost word line WLe0 or WLo0. In the third write operation, the write operation is performed on the memory cell transistor MT belonging to the NAND string 50o selected by the select gate line SGD1 shown in FIG. 5. When the select gate line SGD1 is selected, depending on the voltage supplied to the bit line, the select transistor ST1 facing the wiring layers 10-1a, 10-1b shown in FIG. 5 is turned on or turned off depending on the voltage supplied to the bit line. In FIG. 23, a hatching area of the wiring layer 11o corresponds to the area where the wiring layers 10-1a, 10-1b in FIG. 5 is arranged. That is, when the select gate line SGD1 is selected, the write operation is performed on the memory cell transistor MT facing the wiring layer 11o of the hatching area in FIG. 23.

As shown in FIG. 23, when the select gate line SGD1 (see FIG. 5) is selected, the write operation is performed on the memory cell transistor MT provided on the word line WLo0 side of each of the memory pillars MP0, MP1, MP4, MP5, MP8, MP9, MP12, MP13. In FIG. 23, “3” is indicated at a position corresponding to the memory cell transistor MT to which data has been written by the write operation (the third write operation).

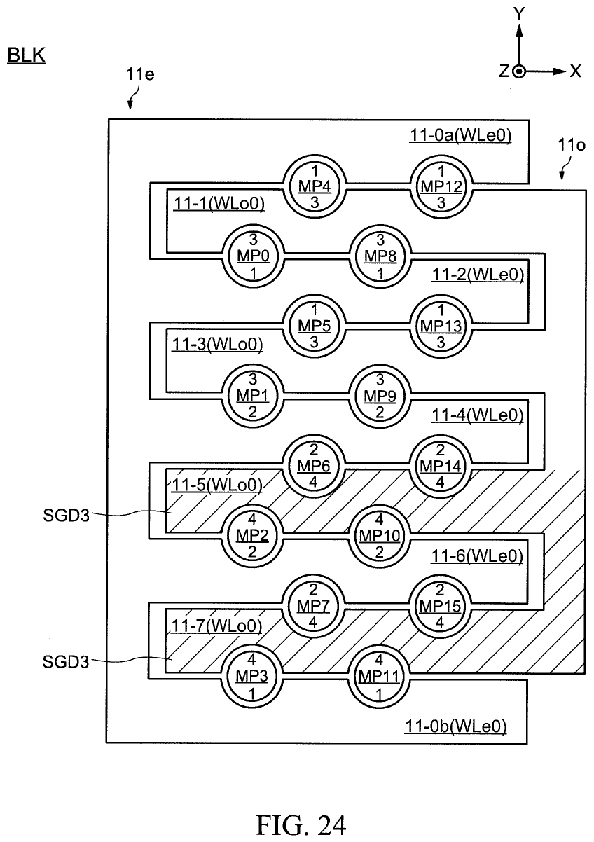

Referring to FIG. 24, a fourth write operation performed following the first to third write operations described above is described. The fourth write operation is a subsequent write operation to the memory cell transistor MT corresponding to the lowermost word line WLe0 or WLo0. In the fourth write operation, the write operation is performed on the memory cell transistor MT belonging to the NAND string 50o selected by the select gate line SGD3 shown in FIG. 5. When the select gate line SGD3 is selected, depending on the voltage supplied to the bit line, the select transistor ST1 facing the wiring layers 10-3a, 10-3b shown in FIG. 5 is turned on or turned off depending on the voltage supplied to the bit line. In FIG. 24, the hatching area of the wiring layer 110 corresponds to the area where the wiring layers 10-3a, 10-3b in FIG. 5 are arranged. That is, when the select gate line SGD3 is selected, the write operation is performed on the memory cell transistor MT facing the wiring layer 11o of the hatching area in FIG. 24.

As shown in FIG. 24, when the select gate line SGD3 (see FIG. 5) is selected, the write operation is performed on the memory cell transistor MT provided on the word line WLo0 side of each of the memory pillars MP2, MP3, MP6, MP7, MP10, MP11, MP14, MP15. In FIG. 24, “4” is indicated at a position corresponding to the memory cell transistor MT to which data has been written by the write operation (the fourth write operation).

By the write operations shown in FIGS. 23 and 24, the write operation to all the memory cell transistors MT facing the word line WLo0 formed in all the memory pillars MP0 to MP15 sandwiched between the word lines WLe0 and WLo0 is completed.

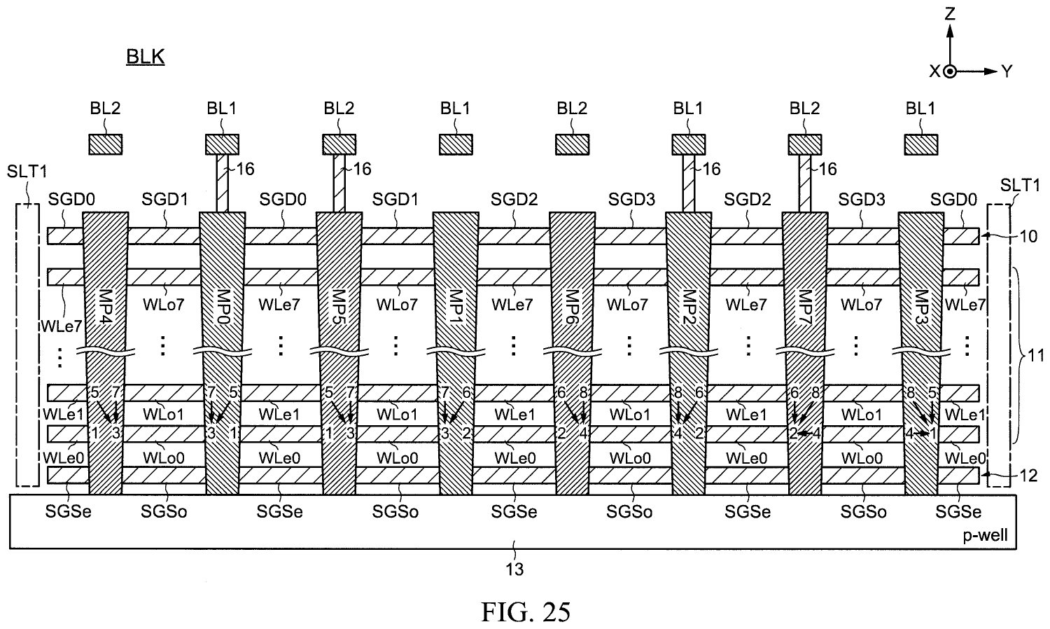

Referring to FIG. 25, an effect of interference caused by the write operation of the other memory cells on the written memory cell will be described. In FIG. 25, the numbers (1 to 4) written on the word line WL side of each memory pillar MP correspond to the numbers indicating the order of the write operation that has been written on each memory pillar MP in FIGS. 21 to 24. Similar to the above, the numbers (5 to 8) shown in FIG. 25 are also numbers indicating the order of the write operation. In FIG. 25, after the write operation to the memory cell transistor MT provided in each memory pillar MP facing the word lines WLe0 and WLo0 is completed, the write operation to the memory cell transistor MT provided in each memory pillar MP facing the word lines WLe1 and WLo1 is performed. The word lines WLe1 and WLo1 are the word lines formed on the wiring layer 11 provided on the upper layer of the word lines WLe0 and WLo0.

In particular, the write operation to the memory cell transistor MT described in the following (1) to (3) causes interference to the target memory cell transistor MT.
(1) A first memory cell transistor MT facing the target memory cell transistor MT (the first memory cell transistor MT formed in the same memory pillar MP as the target memory cell transistor MT, or the first memory cell transistor MT sharing the channel with the target memory cell transistor MT).
(2) A second memory cell transistor MT belonging to the same memory pillar MP as the target memory cell transistor MT and being adjacent to the target memory cell transistor MT in the Z-direction.
(3) A third memory cell transistor MT facing the second memory cell transistor MT.

As described above, when interference to the target memory cell transistor MT occurs, the written data (the threshold voltage varies by injecting the charge into the charge storage layer) in the target memory cell transistor MT may vary. Therefore, in a condition that the number of times that interference occurs in the memory cell transistor MTa is larger than the number of times that interference occurs in the memory cell transistor MTb, it is necessary that a width of the threshold voltage distribution of a memory cell transistor MTa is smaller than a width of the threshold voltage distribution of a memory cell transistor MTb. In the present embodiment, one page is formed corresponding to each of the select gate lines SGD0 to 3. For example, when the select gate line SGD0 is selected, one page is formed by the memory cell transistors MT provided on the word line WLe0 side of each of the memory pillars MP0, MP3, MP4, MP5, MP8, MP11, MP12, MP13, as shown in FIG. 21. For example, even when only a part of the memory cell transistors MT among the memory cell transistors MT belonging to a certain page is affected by the interference, the write operation must be performed considering the width of the threshold voltage distribution after the memory cell transistor MT is interfered. That is, even when only a part of the memory cell transistors MT belonging to a certain page is affected by the interference, the accuracy of the write operation needs to be increased.

As shown in FIG. 25, in the present embodiment, write operation to the memory cell transistor MT on the word line WLe0 side of each of the memory pillar MP is completed by the previous write operation. Thereafter, write operation to the memory cell transistor MT on the word line WLo0 sides of each of the memory pillar MP is performed by the subsequent write operation. In the memory cell transistor MT facing the memory cell transistor MT to which the subsequent write operation is performed, the previous write operation has already been performed. That is, after the previous write operation to the memory cell transistor MT provided on a first side of each of the memory pillar MP among all the memory cell transistors MT facing the word lines WLe0 and WLo0 is completed, the subsequent write operation to the memory cell transistor MT provided on a second side of each of the memory pillar MP is performed.

For the written memory cell transistor MT facing the word line WLe0, the rightmost memory pillar MP3 as shown in FIG. 25, for example, the memory cell transistor MT that is the target of the write operation “1” receives three times of interferences by the write operation “4”, the write operation “5”, and the write operation “8”. Similarly, for example, the second memory pillar MP7 from the right as shown in FIG. 25, the memory cell transistor MT that is the target of the write operation “2” receives three times of interferences by the write operations “4”, “6” and “8”.

On the other hand, with respect to the written memory cell transistor MT facing the word line WLo0, the memory cell transistor MT, which is the target of the write operation “3”, for example, like the four memory pillars MP4, MP0, MP5, MP1 from the left in FIG. 25, receives only two times of interferences by the write operations “5” and “7” or by the write operations “6” and “7”. Similarly, the memory cell transistor MT, which is the target of the write operation “4”, for example, like the third and fourth memory pillars MP2, MP6 from the right in FIG. 25, receives only two times of interferences by the write operations “6” and “8”.

As described above, with respect to the above-described comparative example, in the present embodiment shown in FIGS. 21 to 25, the write operation is performed to two pages. One page is configured with the memory cell transistor MT that receives three times of interferences. Another page is configured with the memory cell transistor MT that receives only two times of interferences. The broadening of the threshold distribution due to interference effects increases as the number of times the interference is received increases. Therefore, since the broadening of the threshold distribution due to the interference effect is smaller, it is possible that the step-up width of program voltage can be set larger to speed up the write operation to the page configured with the memory cell transistor MT receiving only two times of interferences is larger than the step-up width of the write operation to the page configured with the memory cell transistor MT receiving three times of interferences.

### [1-11-4. Grouping of Bit Lines BL]

Grouping of the bit lines BL will be described with reference to FIGS. 5 and 21 to 24. The bit lines are grouped according to combinations of the select gate line SGD for selecting the memory cell transistor MT on which the previous EP operation is performed and the select gate line SGD for selecting the memory cell transistor MT on which the subsequent EP operation is performed.

For example, as shown in FIGS. 22 and 23, when the EP operation is performed on the memory cell transistors MT belonging to the memory pillars MP1, MP9 (the first group GR1), the writing operation is performed simultaneously on both of the memory cell transistors MT facing each other of the same memory pillar MP. For example, when the EP operation is performed on the memory cell transistors MT in the memory pillars MP1, MP9, the select gate line SGD2 needs to be selected to select the memory cell transistor MT facing the word line WLe, and the select gate line SGD1 needs to be selected to select the memory cell transistor MT facing the word line WLo. That is, when the EP operation is performed on the memory cell transistors MT belonging to the memory pillars MP1, MP9, the select gate lines SGD1, SGD2 sandwiching the memory pillars MP are simultaneously selected. Then, a voltage for performing the EP operation to the bit lines BL0, BL4 belonging to the first group GR1 is applied. In this case, since only one of the select gate lines SGD sandwiching the memory pillars MP is selected with respect to the memory pillars MP2, MP6, MP7, MP10, MP14, MP15 belonging to the second group GR2 selected by the select gate line SGD2 and the memory pillars MP0, MP4, MP5, MP8, MP12, MP13 belonging to the second group GR2 selected by the select gate line SGD1, the EP operation needs to be suppressed. To suppress the EP operation, an inhibit voltage for suppressing the EP operation is applied to the bit lines BL1, BL2, BL3, BL5, BL6, BL7 belonging to the second group GR2.

On the other hand, as shown in FIGS. 22 and 24, when the previous EP operation is performed on the memory cell transistors MT belonging to the memory pillars MP2, MP6, MP7, MP10, MP14, MP15 (the second group GR2), the select gate line SGD2 needs to be selected to perform the EP operation on the memory cell transistor MT facing the word line WLe, and the select gate line SGD3 needs to be selected to perform the EP operation on the memory cell transistor MT facing the word line WLo. That is, the select gate lines SGD2, SGD3 sandwiching the memory pillars MP are simultaneously selected. In this case, since only one of the select gate lines SGD sandwiching the memory pillars MP is selected with respect to the memory pillars MP1, MP9, MP3, MP11, the EP operation needs to be suppressed. To suppress the EP operation, the inhibit voltage for suppressing the EP operation is applied to the bit lines BL0, BL4 belonging to the first group GR1.

As described above, the over-erased cell write operation and the verify operation on the memory cell transistors MT as in the present embodiment are collectively performed on the memory cell transistor MT facing each other. Therefore, when the combinations of the select gate lines are different as described above, the over-erased cell write operation and the verify operation need to be performed separately for the first group and the second group.

As shown in FIG. 5, the memory pillars MP1, MP9 of the first group are connected to the bit lines BL0, BL4. On the other hand, the memory pillars MP2, MP6, MP7, MP10, MP14, MP15 of the second group are connected to the bit lines BL1 to BL3, BL5 to BL7. In other words, in the configuration as in FIG. 5, the memory pillars MP of the first group belong to the bit line BL (4n) (n=0, 1, . . . ). The memory pillars MP of the second group belong to bit lines BL (4n+1), BL (4n+2), BL (4n+3) (n=0, 1, . . . ).

When the over-erased cell write operation is performed on the memory cell transistors MT provided in the memory pillars MP belonging to the bit lines of the first group, a voltage VDD is supplied to the bit lines of the second group, and the memory cell transistors MT provided in the memory pillars MP belonging to the bit lines are turned Inhibit. On the other hand, when the over-erased cell write operation is performed on the memory cell transistors MT provided in the memory pillars MP belonging to the bit lines of the second group, the voltage VDD is supplied to the bit lines of the first group, and the memory cell transistors MT provided in the memory pillars MP belonging to the bit lines are turned Inhibit.

### [1-11-5. “Two-Stages Write Operation” and “Two-Layers Cut-Off Read Operation”]

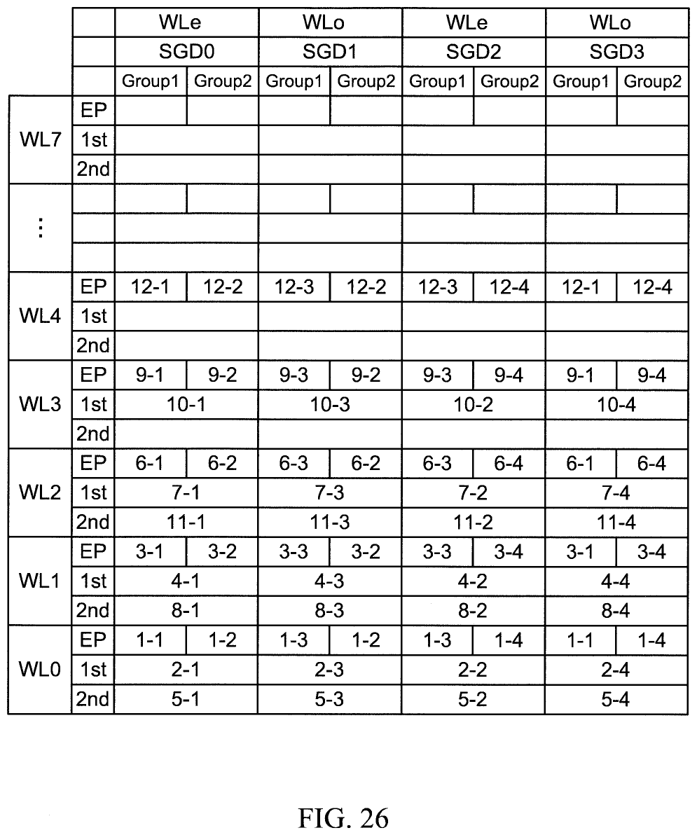

The order of the write operation in “two-stages write operation” and “two-layers cut-off read operation” is described with reference to FIG. 26. The following operation is performed by a control circuit provided in the memory controller 2. In FIG. 26, “WLe” corresponds to the wiring layer 11e of FIGS. 6 and 21 to 24. “WLo” corresponds to the wiring layer 11o in FIGS. 6 and 21 to 24. “SGD0” to “SGD3” correspond to SGD0 to SGD3 shown in FIG. 5. “Group1” and “Group2” correspond to the first group and the second group described above. “WL0” to “WL7” correspond to the word lines WLo0 to WLo7, WLe0 to WLe7 shown in FIGS. 7 and 13. “EP” provided in each of the WL0 to WL7 corresponds to the over erased cell write operation (EP operation) shown in “1-10. Over-erased cell write operation”, and each of “1st” and “2nd” corresponds to the first stage write operation and the second stage write operation in the multi-stages write operation shown in “1-11-1. Two-stages write operation”.

The numerical values described in each item of FIG. 26 indicates the order in which the write operation is performed. Each numerical value is divided into a first half value and a second half value. As for the write operation in which the write operation is performed, the first half value is prioritized, and if the first half value is the same, the write operation is performed in the order of the second half value. In other words, the write operation is performed in the order of “1-1”→“1-2”→“1-3”→“1-4”→“2-1”→“2-2”→ . . . and so on.

As shown in FIG. 26, firstly the EP operation is performed on the memory cells belonging to the word line WL0. As described in “1-11-4. Grouping of bit lines BL”, the EP operation is performed separately for the first group and the second group. Specifically, first, in “1-1”, the EP operation is performed on the memory cells belonging to the Group1 of the SGD0 and SGD3 (the memory cell transistors MT belonging to the memory pillars MP3, MP11). Next, in “1-2”, the EP operation is performed on the memory cells belonging to the Group2 of the SGD0 and SGD1 (the memory cell transistors MT belonging to the memory pillars MP0, MP4, MP5, MP8, MP12, MP13). Next, in “1-3”, the EP operation is performed on the memory cells belonging to the Group1 of the SGD1 and SGD2 (the memory cell transistors MT belonging to the memory pillars MP1, MP9). Next, in “1-4”, the EP operation is performed on the memory cells belonging to the Group2 of the SGD2 and SGD3 (the memory cell transistors MT belonging to the memory pillars MP2, MP6, MP7, MP10, MP14, MP15).

Following the EP operation for the memory cells belonging to the word line WL0 described above, the first stage write operation is performed on the memory cells belonging to the word line WL0 in “2-1” to “2-4”. The first stage write operation is performed in the order of SGD0→SGD2→SGD1→SGD3 as shown in FIGS. 21 to 24.

Following the first stage write operation for the word line WL0, the EP operation is performed on the memory cells belonging to a word line WL1 in “3-1” to “3-4”. Since the EP operation for the memory cells belonging to the word line WL1 is the same as the EP operation for the memory cells belonging to the word line WL0, a detailed explanation is omitted. Following the EP operation for the memory cells belonging to the word line WL1, the first stage write operation is performed on the memory cells belonging to the word line WL1 in “4-1” to “4-4”. Since the first stage write operation is the same as the first stage write operation for the memory cells belonging to the word line WL0 described above, a detailed explanation thereof is omitted.

Following the first stage write operation for the memory cells belonging to the word line WL1 described above, the second stage write operation is performed on the memory cells belonging to the word line WL0 in “5-1” to “5-4”. The second stage write operation is performed in the order of SGD0→SGD2→SGD1→SGD3 as shown in FIGS. 21 to 24.

Following the second stage write operation for the word line WL0, the EP operation is performed on the memory cells belonging to a word line WL2 in “6-1” to “6-4”, the first stage write operation is performed in “7-1” to “7-4”, and then the second stage write operation is performed on the memory cells belonging to the word line WL1 in “8-1” to “8-4”.

As described above, the EP operation and the first stage write operation are performed on the memory cells belonging to the word line WL (n), the second stage write operation is performed on the memory cells belonging to the word line WL (n−1), and then the EP operation is performed on the memory cells belonging to the word line WL (n+1).

The memory cell transistors MT belonging to the memory pillar MP0 will be described with reference to the above-described operation. The memory cell transistor MT belonging to a WLe3 is referred to as the “first memory cell”. The memory cell transistor MT belonging to a WLo3 is referred to as the “second memory cell”. The memory cell transistor MT belonging to a WLe2 is referred to as the “third memory cell”. The memory cell transistor MT belonging to a WLo2 is referred to as the “fourth memory cell”. The memory cell transistor MT belonging to the WLe1 is referred to as the “fifth memory cell”. The memory cell transistor MT belonging to the WLo1 is referred to as the “sixth memory cell”.

The control circuit provided in the memory controller 2 performs the EP operation (initial write operation), the first stage write operation (first write operation), and the second stage write operation (second write operation) for each of the first to sixth memory cells.

Specifically, the EP operation is performed on the third memory cell belonging to the WLe2 and the fourth memory cell belonging to the WLo2 (“6-1” to “6-4”). Subsequently, the first write operation is performed on the third memory cell (“7-1”, “7-2”), and the first write operation is performed on the fourth memory cell (“7-3”, “7-4”). Subsequently, the second write operation is performed on the fifth memory cell belonging to the WLe1 (“8-1”, “8-2”), and the second write operation is performed on the sixth memory cell belonging to the WLo1 (“8-3”, “8-4”). Subsequently, the EP operation is performed on the first memory cell belonging to the WLe3 and the second memory cell belonging to the WLo3 (“9-1” to “9-4”). Subsequently, the first write operation is performed on the first memory cell (“10-1”, “10-2”), and the first write operation is performed on the second memory cell (“10-3”, “10-4”). Subsequently, the second write operation is performed on the third memory cell (“11-1”, “11-2”), and the second write operation is performed on the fourth memory cell (“11-3”, “11-4”).

### [1-11-6. “Two-Stages Write Operation” and “Three-Layers Cut-Off Read Operation”]

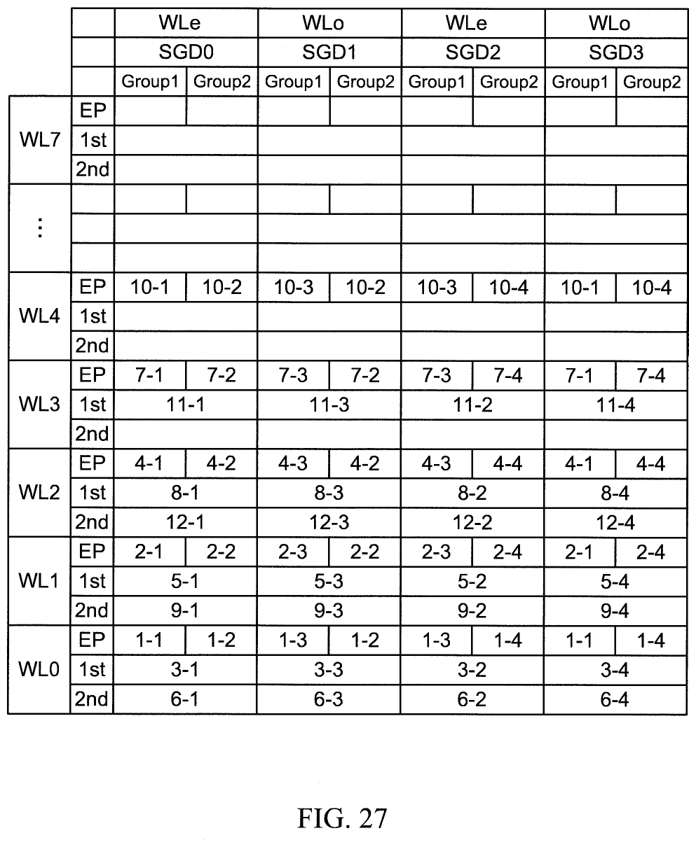

The order of the write operation in “two-stages write operation” and “three-layers cut-off read operation” is described with reference to FIG. 27. The following operation is performed by the control circuit provided in the memory controller 2. In the three-layers cut-off read operation, as shown in FIG. 15, the memory cell provided in the upper layer of the memory cell to be read needs to be forcibly turned off. Therefore, the first stage write operation cannot be performed immediately after the EP operation for the same word line as in the operation shown in FIG. 26. Therefore, although the details will be described later, the EP operation needs to be performed on the memory cells belonging to the word line WL (n+1) before the write operation on the word line WL (n) to which the memory cell to be written belongs (n is a natural number). In the following description, since the order of the EP operation, the first stage write operation, and the second stage write operation in each word line is the same as that in FIG. 26, the description of the order of each operation in each word line is omitted.

As shown in FIG. 27, firstly the EP operation is performed on the memory cells belonging to the word line WL0 (“1-1” to “1-4”). Subsequently, the EP operation is performed on the memory cells belonging to the word line WL1 (“2-1” to “2-4”). Subsequently, the first stage write operation is performed on the memory cells belonging to the word line WL0 (“3-1” to “3-4”). Subsequently, the EP operation is performed on the memory cells belonging to the word line WL2 (“4-1” to “4-4”). Subsequently, the first stage write operation is performed on the memory cells belonging to the word line WL1 (“5-1” to “5-4”). Subsequently, the second stage write operation is performed on the memory cells belonging to the word line WL0 (“6-1” to “6-4”). Subsequently, the EP operation is performed on the memory cells belonging to a word line WL3 (“7-1” to “7-4”).

As described above, the EP operation is performed on the memory cells belonging to the word line WL (n), then the first stage write operation is performed on the memory cells belonging to the word line WL (n−1), then the second stage write operation is performed on the memory cells belonging to the word line WL (n−2), and then the EP operation is performed on the memory cells belonging to the word line WL (n+1).

The memory cell transistor MT belonging to the memory pillar MP0 will be described with reference to the above-described operation. The memory cell transistor MT belonging to the WLe0 is referred to as the “seventh memory cell”. The memory cell transistor MT belonging to the WLo0 is referred to as the “eighth memory cell”.

Specifically, the EP operation is performed on the third memory cell belonging to the WLe2 and the fourth memory cell belonging to the WLo2 (“4-1” to “4-4”). Subsequently, the first write operation is performed on the fifth memory cell belonging to the WLe1 (“5-1”, “5-2”), and the first write operation is performed on the sixth memory cell belonging to the WLo1 (“5-3”, “5-4”). Subsequently, the second write operation is performed on the seventh memory cell belonging to the WLe0 (“6-1”, “6-2”), and the second write operation is performed on the eighth memory cell belonging to the WLo1 (“6-3”, “6-4”). Subsequently, the EP operation is performed on the first memory cell belonging to the WLe3 and the second memory cell belonging to the WLo3 (“7-1” to “7-4”). Subsequently, the first write operation is performed on the third memory cell (“8-1”, “8-2”), and the first write operation is performed on the fourth memory cell (“8-3”, “8-4”). Subsequently, the second write operation is performed on the fifth memory cell (“9-1”, “9-2”), and the second write operation is performed on the sixth memory cell (“9-3”, “9-4”).

### [1-11-7. “Three-Stages Write Operation” and “Two-Layers Cut-Off Read Operation”]

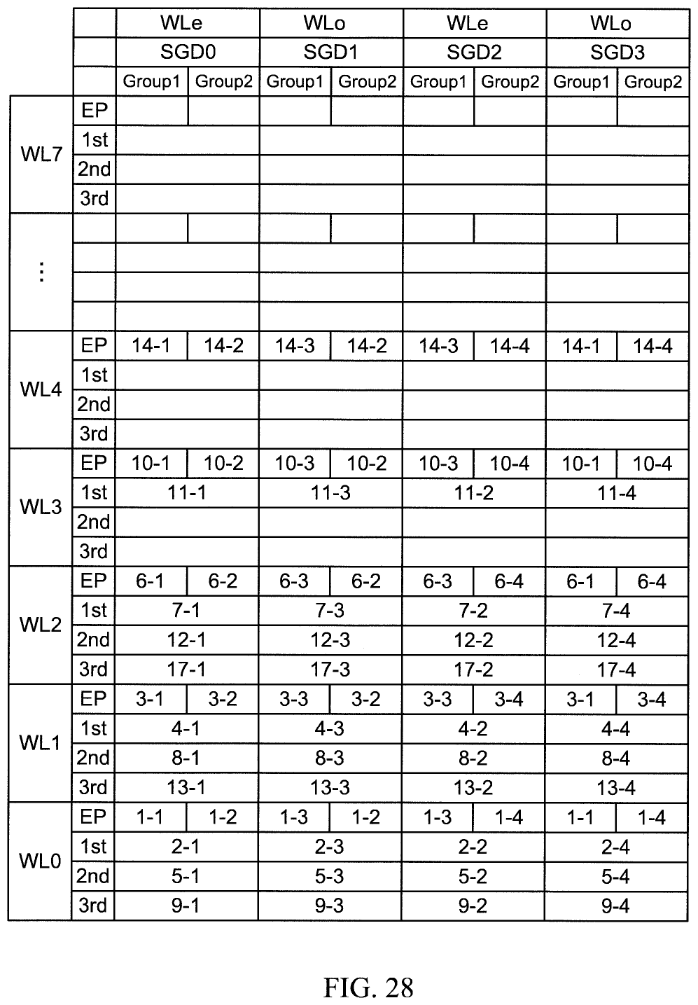

The order of the write operation in “three-stages write operation” and “two-layers cut-off read operation” is described with reference to FIG. 28. The following operation is performed by the control circuit provided in the memory controller 2. In the following description, since the order of the EP operation, the first stage write operation, and the second stage write operation in each word line is the same as that in FIG. 26, the description of the order of each operation in each word line is omitted. The order of a third-stage write operation in each word line is the same as the order of the first stage write operation and the second-stage write operation, and therefore the description thereof is omitted. “3rd” corresponds to the third stage write operation in the multi-stages write shown in “1-11-2. Three-stages write operation”.

As shown in FIG. 28, firstly the EP operation (“1-1” to “1-4”) and the first stage write operation (“2-1” to “2-4”) are performed on the memory cells belonging to the word line WL0. Subsequently, the EP operation (“3-1” to “3-4”) and first stage write operation (“4-1” to “4-4”) are performed on the memory cells belonging to the word line WL1. Subsequently, the second stage write operation is performed on the memory cells belonging to the word line WL0 (“5-1” to “5-4”). Subsequently, the EP operation (“6-1” to “6-4”) and first stage write operation (“7-1” to “7-4”) are performed on the memory cells belonging to the word line WL2. Subsequently, the second stage write operation is performed on the memory cells belonging to the word line WL1 (“8-1” to “8-4”). Subsequently, the third-stage write operation is performed on the memory cells belonging to the word line WL0 (“9-1” to “9-4”). Subsequently, the EP operation (“10-1” to “10-4”) and first stage write operation (“11-1” to “11-4”) are performed on the memory cells belonging to the word line WL3.

As described above, the EP operation and the first stage write operation are performed on the memory cells belonging to the word line WL (n), the second stage write operation is performed on the memory cells belonging to the word line WL (n−1), the third stage write operation is performed on the memory cells belonging to the word line WL (n−2), and then the EP operation and the first stage write operation are performed on the memory cells belonging to the word line WL (n+1) (n is a natural number).

The control circuit provided in the memory controller 2 performs the EP operation (initial write operation), the first stage write operation (first write operation), the second stage write operation (second write operation), and the third stage write operation (third write operation) for each of the first to eighth memory cells.

Specifically, after the second write operation (“8-3”, “8-4”) for the sixth memory cell, the third write operation is performed on the seventh memory cell belonging to the WLe0 (“9-1”, “9-2”), and the third write operation is performed on the eighth memory cell belonging to the WLo0 (“9-3”, “9-4”). Subsequently, the EP operation is performed on the first memory cell belonging to the WLe3 and the second memory cell belonging to the WLo3 (“10-1” to “10-4”). After the second write operation (“12-3”, “12-4”) for the fourth memory cell, the third write operation is performed on the fifth memory cell (“13-1”, “13-2”), and the third write operation is performed on the sixth memory cell (“13-3”, “13-4”).

### [1-11-8. “Three-Stages Write Operation” and “Three-Layers Cut-Off Read Operation”]

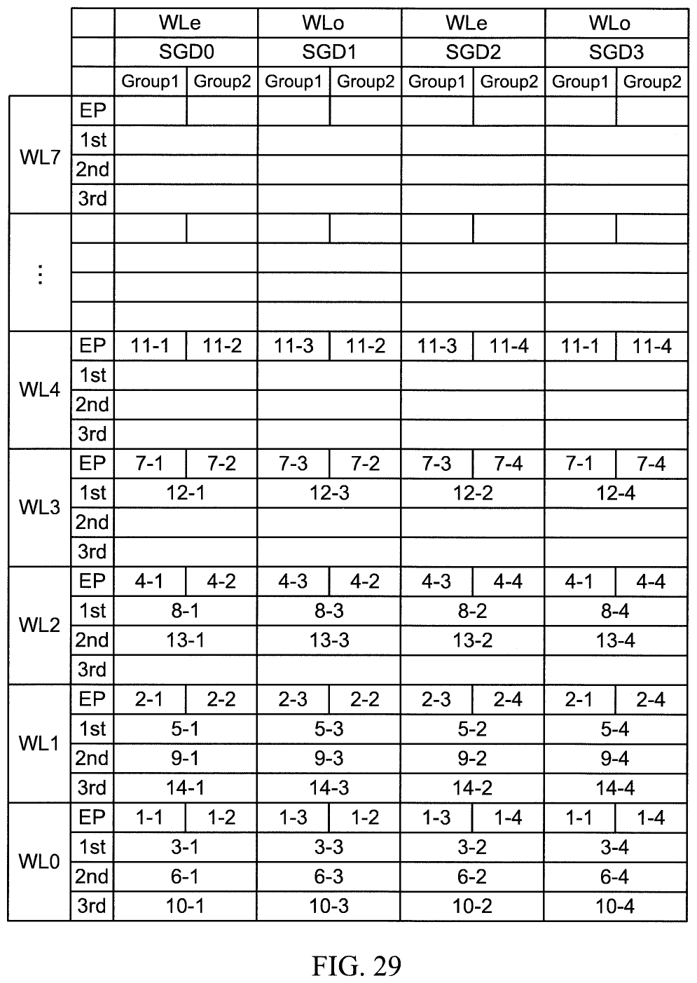

The order of the write operation in “three-stages write operation” and “three-layers cut-off read operation” is described with reference to FIG. 29. The following operation is performed by the control circuit provided in the memory controller 2. In the following description, since the order of the EP operation, the first stage write operation, the second stage write operation, and the third stage write operation in each word line is the same as that in FIG. 28, the description of the order of each operation in each word line is omitted.

As shown in FIG. 29, firstly the EP operation (“1-1” to “1-4”) is performed on the memory cells belonging to the word line WL0. Subsequently, the EP operation (“2-1” to “2-4”) is performed on the memory cells belonging to the word line WL1. Subsequently, the first stage write operation is performed on the memory cells belonging to the word line WL0 (“3-1” to “3-4”). Subsequently, the EP operation (“4-1” to “4-4”) is performed on the memory cells belonging to the word line WL2. Subsequently, the first stage write operation is performed on the memory cells belonging to the word line WL1 (“5-1” to “5-4”). Subsequently, the second stage write operation is performed on the memory cells belonging to the word line WL0 (“6-1” to “6-4”). Subsequently, the EP operation (“7-1” to “7-4”) is performed on the memory cells belonging to the word line WL3. Subsequently, the first stage write operation is performed on the memory cells belonging to the word line WL2 (“8-1” to “8-4”). Subsequently, the second stage write operation is performed on the memory cells belonging to the word line WL1 (“9-1” to “9-4”). Subsequently, the third stage write operation is performed on the memory cells belonging to the word line WL0 (“10-1” to “10-4”). Subsequently, the EP operation (“11-1” to “11-4”) is performed on the memory cells belonging to the word line WL4.

As described above, the EP operation is performed on the memory cells belonging to the word line WL (n), subsequently, the first stage write operation is performed on the memory cells belonging to the word line WL (n−1), subsequently, the second stage write operation is performed on the memory cells belonging to the word line WL (n−2), subsequently, the third stage write operation is performed on the memory cells belonging to the word line WL (n−3), subsequently, the EP operation is performed on the memory cells belonging to the word line WL (n+1) (n is a natural number).

The memory cell transistors MT belonging to the memory pillar MP0 will be described with reference to the above-described operation. The memory cell transistor MT belonging to a WLe4 is referred to as the “first memory cell”. The memory cell transistor MT belonging to a WLo4 is referred to as the “second memory cell”. The memory cell transistor MT belonging to the WLe3 is referred to as the “third memory cell”. The memory cell transistor MT belonging to the WLo3 is referred to as the “fourth memory cell”. The memory cell transistor MT belonging to the WLe2 is referred to as the “fifth memory cell”. The memory cell transistor MT belonging to the WLo2 is referred to as the “sixth memory cell”. The memory cell transistor MT belonging to the WLe1 is referred to as the “seventh memory cell”. The memory cell transistor MT belonging to the WLo1 is referred to as the “eighth memory cell”. The memory cell transistor MT belonging to the WLe0 is referred to as the “ninth memory cell”. The memory cell transistor MT belonging to the WLo0 is referred to as the “tenth memory cell”.

The control circuit provided in the memory controller 2 performs the EP operation (initial write operation), the first stage write operation (first write operation), the second stage write operation (second write operation), and the third stage write operation (third write operation) for each of the first to tenth memory cells.

Specifically, the EP operation is performed on the third memory cell belonging to the WLe3 and the fourth memory cell belonging to the WLo3 (“7-1” to “7-4”). Subsequently, the first write operation is performed on the fifth memory cell belonging to the WLe2 (“8-1”, “8-2”), and the first write operation is performed on the sixth memory cell belonging to the WLo2 (“8-3”, “8-4”). Subsequently, the second write operation is performed on the seventh memory cell belonging to the WLe1 (“9-1”, “9-2”), and the second write operation is performed on the eighth memory cell belonging to the WLo1 (“9-3”, “9-4”). Subsequently, the third write operation is performed on the ninth memory cell belonging to the WLe0 (“10-1”, “10-2”), and the third write operation is performed on the tenth memory cell belonging to the WLo0 (“10-3”, “10-4”). Subsequently, the EP operation is performed on the first memory cell belonging to the WLe4 and the second memory cell belonging to the WLo4 (“11-1” to “11-4”). Subsequently, the first write operation is performed on the third memory cell (“12-1”, “12-2”), and the first write operation is performed on the fourth memory cell (“12-3”, “12-4”). Subsequently, the second write operation is performed on the fifth memory cell (“13-1”, “13-2”), and the second write operation is performed on the sixth memory cell (“13-3”, “13-4”). Subsequently, the third write operation is performed on the seventh memory cell (“14-1”, “14-2”), and the third write operation is performed on the eighth memory cell (“14-3”, “14-4”).

As described above, according to the memory system of the present embodiment, even when the multi-stages write operation is performed in the memory system in which the channels of the memory cell transistors MT facing each other share a part of the memory pillar MP as in the memory system of the present embodiment, erroneous writing and erroneous reading can be suppressed.

### Second Embodiment

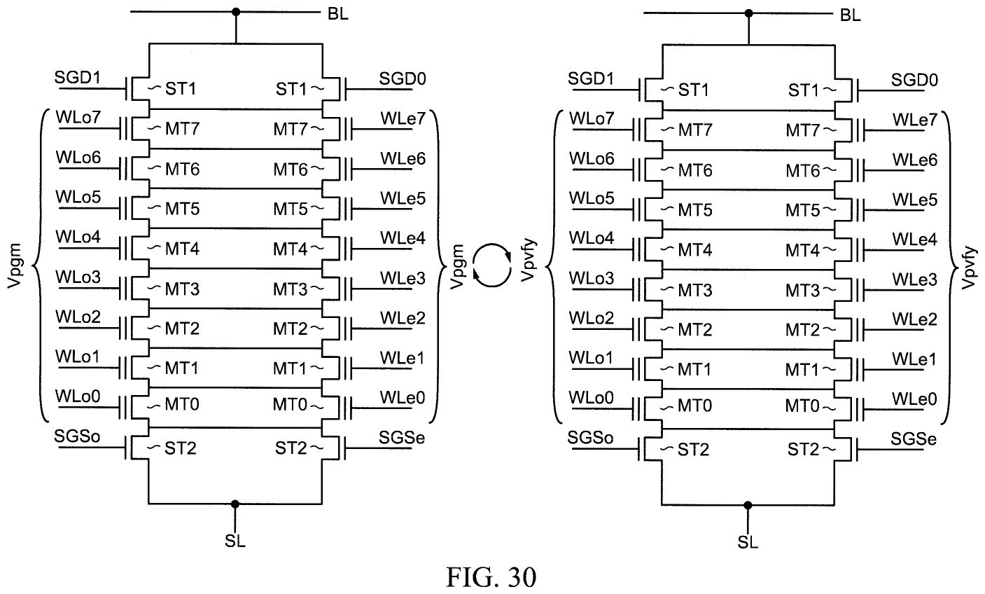

The memory system according to the second embodiment will be described with reference to FIGS. 30 to 33. The write operation of the memory system according to the second embodiment is different from the write operation of the memory system according to the first embodiment. In other respects, the second embodiment has the same configuration as that of the first embodiment, and therefore description thereof is omitted.

In the first embodiment, the over-erased cell write operation is performed immediately before the write operation on the memory cell is performed, but in the second embodiment, for example, the over-erased cell write operation (EP operation) is performed on the plurality of word lines WL after the erase operation on the page-by-page or block-by-block memory cell.

FIG. 30 is a diagram illustrating a batch EP operation and a batch verify operation in the semiconductor storage device according to an embodiment. As shown in FIG. 30, the over-erased cell write voltage Vpgm is collectively supplied to all word lines WL (in the examples of FIG. 30, the word lines WL0 to WL7). This operation is referred to as the “batch EP operation”. Thereafter, the verify voltage Vpvfy is collectively supplied to all word lines WL. This operation is referred to as the “batch verify operation”. The batch EP operation and the batch verify operation are alternately repeated a plurality of times. As described above, in the present embodiment, the EP operation is collectively performed on all the effective memory cells provided in the memory pillar MP. An “effective” memory cell is a memory cell in which the write operation or the read operation is performed by a write request or a read request of the memory controller 2, and it means to exclude dummy cells and the like.

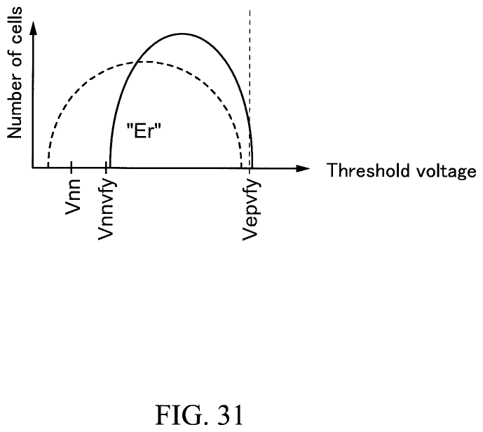

FIG. 31 is a diagram illustrating the verify operation in the semiconductor storage device according to an embodiment. A graph shown in FIG. 31 is a threshold voltage distribution in the “Er” state before and after the batch EP operation. The threshold voltage distribution indicated by the dotted line in FIG. 31 is the threshold voltage distribution immediately after the erase operation, and the threshold voltage distribution indicated by the solid line is the threshold voltage distribution after the batch EP operation.

As in the present embodiment, when the batch EP operation and the batch verify operation are performed, the current flowing through the NAND string is interrupted when the lower tail of the threshold voltage distribution becomes higher than the voltage Vnnvfy at any one of the memory cell transistors MT connected in series in the NAND string. Therefore, it is difficult to identify the memory cell transistor MT in which the lower tail of the threshold voltage distribution exceeds the voltage Vnnvfy among the memory cell transistors MT included in the NAND string when the verify operation is performed with the voltage Vnnvfy at the lower tail of the threshold voltage distribution.

To solve the above problems, in the present embodiment, as shown in FIG. 31, the verify operation is performed based on a voltage Vepvfy at the upper tail of the threshold voltage distribution (i.e., the voltage value of the high voltage side of the threshold voltage distribution). The value of the voltage Vepvfy is determined based on the voltage Vnnvfy and the profile of the threshold voltage distribution after the expected EP operation.

Even when the EP operation is collectively performed on the plurality of word lines WL, two select gate lines SGD sandwiching the memory pillars MP are simultaneously selected to simultaneously perform the write operation on both of the memory cell transistors MT facing each other. For example, when the EP operation is performed on the memory cell transistor MT facing the plurality of word lines WL among the memory cell transistors MT formed in the memory pillars MP1, MP9, the select gate line SGD2 needs to be selected to select the memory cell transistor MT facing the word line WLe, and the select gate line SGD1 needs to be selected to select the memory cell transistor MT facing the word line WLo. That is, when the EP operation is performed on the memory cell transistors MT belonging to the memory pillars MP1, MP9, the select gate lines SGD1, SGD2 sandwiching the memory pillars MP are simultaneously selected. Then, a voltage for performing the EP operation on the bit lines BL0, BL4 belonging to the first group GR1 is applied. In this case, since only one of the select gate lines SGD sandwiching the memory pillars MP is selected with respect to MP2, MP6, MP7, MP10, MP14, MP15 belonging to the second group GR2 selected by the select gate line SGD2, and MP0, MP4, MP5, MP8, MP12, MP13 belonging to the second group GR2 selected by the select gate line SGD1, the EP operation needs to be suppressed. To suppress the EP operation, the inhibit voltage for suppressing the EP operation is applied to the bit lines BL1, BL2, BL3, BL5, BL6, BL7 belonging to the second group GR2.

On the other hand, as shown in FIGS. 22 and 24, when the previous EP operation is performed on the memory cell transistors MT belonging to the memory pillars MP2, MP6, MP7, MP10, MP14, MP15 (the second group GR2), the select gate line SGD2 needs to be selected to perform the EP operation on the memory cell transistor MT facing the word line WLe, and the select gate line SGD3 needs to be selected to perform the EP operation on the memory cell transistor MT facing the word line WLo. That is, the select gate lines SGD2, SGD3 sandwiching the memory pillars MP are simultaneously selected. In this case, since only one of the select gate lines SGD sandwiching the memory pillars MP is selected with respect to the memory pillars MP1, MP9, MP3, MP11, the EP operation needs to be suppressed. To suppress the EP operation, the inhibit voltage for suppressing the EP operation is applied to the bit lines BL0, BL4 belonging to the first group GR1.

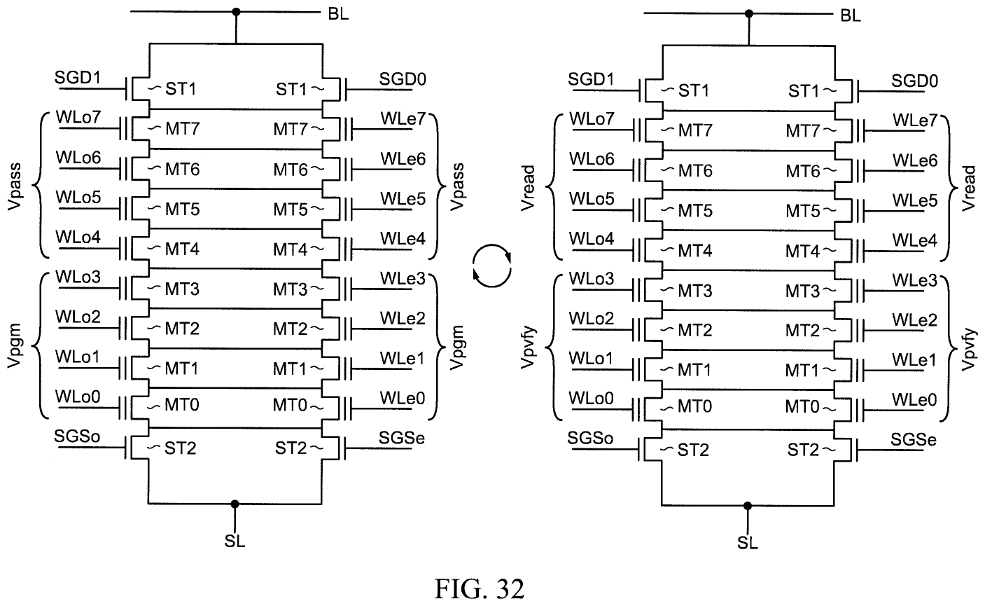

Although the EP operation and the verify operation are collectively performed on all the memory cell transistors MT included in the NAND string in FIG. 30, the EP operation and verify operation may be collectively performed on some of the memory cell transistors MT included in the NAND string as shown in FIG. 32.

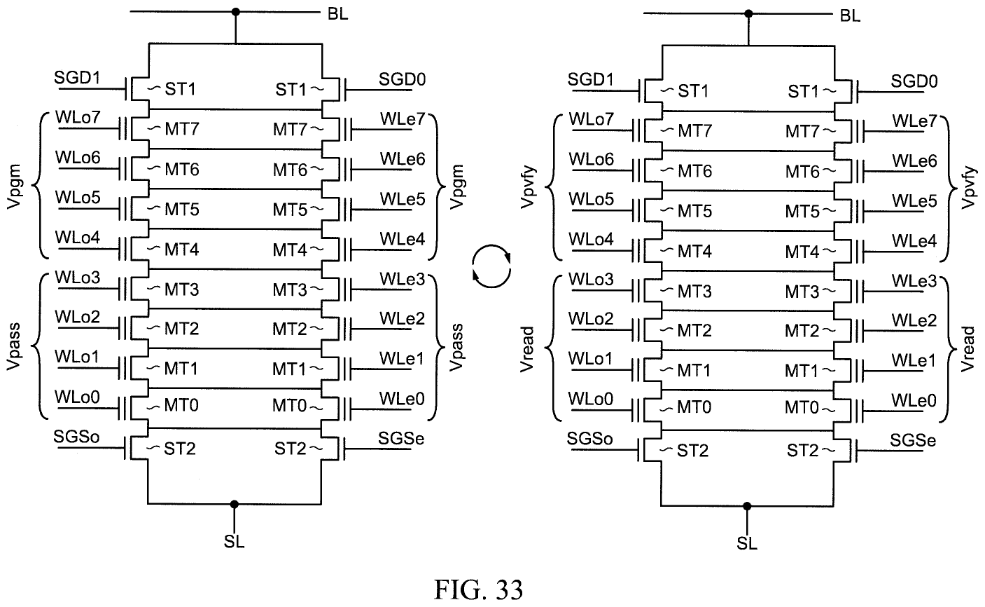

In FIG. 32, the batch EP operation and the batch verify operation are performed on the word lines WL0 to WL3 in the first half of the word lines WL0 to WL7. If the batch EP operation is performed on the first half of the word lines WL0 to WL3, the word lines WL0 to WL3 are supplied with the Vpgm, and the remaining word lines WL4 to WL7 are supplied with the Vpass. When the verify operation is performed on the first half of word lines WL0 to WL3, the word lines WL0 to WL3 are supplied with the Vpvfy, and the remaining word lines WL4 to WL7 are supplied with the Vread. The batch EP operation and the batch verify operation are alternately repeated a plurality of times. Following the above operation, as shown in FIG. 33, the batch EP operation and the batch verify operation are alternately repeated a plurality of times for the word lines WL4 to WL7 in the second half.

While the present invention has been described with reference to the accompanying drawings, the present invention is not limited to the above embodiments and can be appropriately modified without departing from the spirit of the present invention. For example, a skilled in the art who adds, deletes, or changes designs of components as appropriate based on the compression/decompression circuit of the present embodiment is also included in the scope of the present invention as long as the gist of the present invention is provided. Furthermore, the embodiments described above can be appropriately combined as long as there is no mutual inconsistency, and technical matters common to the embodiments are included in the embodiments even if they are not explicitly described.

Even if it is other working effects which is different from the working effect brought about by the mode of each above-mentioned embodiment, what is clear from the description in this description, or what can be easily predicted by the person skilled in the art is naturally understood to be brought about by the present invention.

What is claimed is:

1. A memory system comprising:
a first word line provided in a first layer;
a second word line provided in the first layer and configured to be controlled independently from the first word line;
a third word line provided in a second layer being adjacent to the first layer in a vertical direction;
a fourth word line provided in the second layer and configured to be controlled independently from the third word line;
a fifth word line provided in a third layer being adjacent to the second layer in the vertical direction;
a sixth word line provided in the third layer and configured to be controlled independently from the fifth word line;
a plurality of memory pillars
each extending in the vertical direction to be
sandwiched by the first word line and the second word line,
sandwiched by the third word line and the fourth word line,
sandwiched by the fifth word line and the sixth word line, and
each including
a first memory cell facing the first word line,
a second memory cell facing the second word line,
a third memory cell facing the third word line,
a fourth memory cell facing the fourth word line,
a fifth memory cell facing the fifth word line and
a sixth memory cell facing the sixth word line; and
a control circuit configured to perform
an initial write operation in which a threshold voltage of a subject memory cell is increased from a first level to a second level, the first level corresponding to an erased state, the second level corresponding to a level no less than a minimum voltage supplied in a read operation,
a first write operation after the initial write operation and
a second write operation after the first write operation,
wherein the control circuit is configured to perform
the initial write operation on the third memory cells and the fourth memory cells,
the first write operation on the third memory cells,
the first write operation on the fourth memory cells,
the second write operation on the fifth memory cells,
the second write operation on the sixth memory cells, and
the initial write operation on the first memory cells and the second memory cells.

2. The memory system according to claim 1, further comprising:
a first select gate line configured to control a first memory string provided with each of the plurality of memory pillars including the first memory cell, the third memory cell and the fifth memory cell; and
a second select gate line configured to control a second memory string provided with each of the plurality of memory pillars including the second memory cell, the fourth memory cell and the sixth memory cell,
wherein
each of the plurality of memory pillars includes
a first group memory pillar sandwiched by the first select gate line and the second select gate line,
a second group memory pillar being adjacent to the first select gate line or the second select gate line, and sandwiched by the first select gate line or the second select gate line and the other select gate line, and
the control circuit is configured to perform
the initial write operation on a memory cell belonging to the second group memory pillar after performing the initial write operation on a memory cell belonging to the first group memory pillar.

3. The memory system according to claim 1, further comprising:
a seventh word line provided in a fourth layer being adjacent to the third layer in the vertical direction; and
an eighth word line provided in the fourth layer and configured to be controlled independently from the seventh word line,
wherein
each of the plurality of memory pillars is sandwiched by the seventh word line and the eighth word line,
each of the plurality of memory pillars further includes
a seventh memory cell facing the seventh word line and
an eighth memory cell facing the eighth word line,
the control circuit is configured to perform
the initial write operation, the first write operation, the second write operation and a third write operation after the second write operation on each of the first memory cell to the eighth memory cell,
the third write operation on the seventh memory cell and the third write operation on the eighth memory cell after the second write operation on the sixth memory cell,
the initial write operation on the first memory cell and the second memory cell after the third write operation on the eighth memory cell,
the third write operation on the fifth memory cell and the third write operation on the sixth memory cell after the second write operation on the fourth memory cell.

4. The memory system according to claim 3, further comprising:
a first select gate line configured to control a first memory string provided with each of the plurality of memory pillars including the first memory cell, the third memory cell, the fifth memory cell and the seventh memory cell; and
a second select gate line configured to control a second memory string provided with each of the plurality of memory pillars including the second memory cell, the fourth memory cell, the sixth memory cell and the eighth memory cell,
wherein
each of the plurality of memory pillars includes
a first group memory pillar sandwiched by the first select gate line and the second select gate line,
a second group memory pillar being adjacent to the first select gate line or the second select gate line, and sandwiched by the first select gate line or the second select gate line and the other select gate line, and
the control circuit performs the initial write operation on a memory cell belonging to the second group memory pillar after performing the initial write operation on a memory cell belonging to the first group memory pillar.

5. A memory system comprising:
a first word line provided in a first layer;
a second word line provided in the first layer and configured to be controlled independently from the first word line;
a third word line provided in a second layer being adjacent to the first layer in a vertical direction;
a fourth word line provided in the second layer and configured to be controlled independently from the third word line;
a fifth word line provided in a third layer being adjacent to the second layer in the vertical direction;
a sixth word line provided in the third layer and configured to be controlled independently from the fifth word line;
a seventh word line provided in a fourth layer being adjacent to the third layer in the vertical direction;
an eighth word line provided in the fourth layer and configured to be controlled independently from the seventh word line;
a plurality of memory pillars
each extending in the vertical direction to be
sandwiched by the first word line and the second word line,
sandwiched by the third word line and the fourth word line,
sandwiched by the fifth word line and the sixth word line, and
sandwiched by the seventh word line and the eighth word line, and
each including
a first memory cell facing the first word line,
a second memory cell facing the second word line,
a third memory cell facing the third word line,
a fourth memory cell facing the fourth word line,
a fifth memory cell facing the fifth word line,
a sixth memory cell facing the sixth word line,
a seventh memory cell facing the seventh word line and
an eighth memory cell facing the eighth word line; and
a control circuit configured to perform
an initial write operation in which a threshold voltage of a subject memory cell is increased from a first level to a second level, the first level corresponding to an erased state, the second level corresponding to a level no less than a minimum voltage supplied in a read operation,
a first write operation after the initial write operation and
a second write operation after the first write operation,
wherein the control circuit is configured to perform
the initial write operation on the third memory cells and the fourth memory cells,
the first write operation on the fifth memory cells,
the first write operation on the sixth memory cells,
the second write operation on the seventh memory cells,
the second write operation on the eighth memory cells, and
the initial write operation on the first memory cells and the second memory cells.

6. The memory system according to claim 5, further comprising:
a first select gate line configured to control a first memory string provided with each of the plurality of memory pillars including the first memory cell, the third memory cell, the fifth memory cell and the seventh memory cell; and
a second select gate line configured to control a second memory string provided with each of the plurality of memory pillars including the second memory cell, the fourth memory cell, the sixth memory cell and the eighth memory cell,
wherein
each of the plurality of memory pillars includes
a first group memory pillar sandwiched by the first select gate line and the second select gate line,
a second group memory pillar being adjacent to the first select gate line or the second select gate line, and sandwiched by the first select gate line or the second select gate line and the other select gate line, and
the control circuit is configured to perform
the initial write operation on a memory cell belonging to the second group memory pillar after performing the initial write operation on a memory cell belonging to the first group memory pillar.

7. The memory system according to claim 6, further comprising:
a ninth word line provided in a fifth layer being adjacent to the fourth layer in the vertical direction; and
a tenth word line provided in the fifth layer and configured to be controlled independently from the ninth word line,
wherein
each of the plurality of memory pillars is sandwiched by the ninth word line and the tenth word line,
each of the plurality of memory pillars further includes
a ninth memory cell facing the ninth word line and
a tenth memory cell facing the tenth word line,
the control circuit is configured to perform
the initial write operation, the first write operation, the second write operation and a third write operation after the second write operation on each of the first memory cell to the tenth memory cell,
the third write operation on the ninth memory cell and the third write operation on the tenth memory cell after the second write operation on the eighth memory cell,
the initial write operation on the first memory cell and the second memory cell after the third write operation on the tenth memory cell,
the third write operation on the seventh memory cell and the third write operation on the eighth memory cell after the second write operation on the sixth memory cell.

8. The memory system according to claim 7, further comprising:
a first select gate line configured to control a first memory string provided with each of the plurality of memory pillars including the first memory cell, the third memory cell, the fifth memory cell, the seventh memory cell and the ninth memory cell; and
a second select gate line configured to control a second memory string provided with each of the plurality of memory pillars including the second memory cell, the fourth memory cell, the sixth memory cell, the eighth memory cell and the tenth memory cell,
wherein
each of the plurality of memory pillars includes
a first group memory pillar sandwiched by the first select gate line and the second select gate line,
a second group memory pillar being adjacent to the first select gate line or the second select gate line, and sandwiched by the first select gate line or the second select gate line and the other select gate line, and
the control circuit performs the initial write operation on a memory cell belonging to the second group memory pillar after performing the initial write operation on a memory cell belonging to the first group memory pillar.

9. A memory system comprising:
a first word line and a second word line configured to be controlled independently from the first word line, the first word line and the second word line being provided in each of a plurality of layers;
a plurality of memory pillars
each extending in the vertical direction to be
sandwiched by the first word line and the second word line, and
each including
a first memory cell facing the first word line and
a second memory cell facing the second word line; and
a control circuit configured to perform an initial write operation in which a threshold voltage of a subject memory cell is increased from a first level to a second level, the first level corresponding to an erased state, the second level corresponding to a level no less than a minimum voltage supplied in a read operation, after an erase operation on the first memory cell and the second memory cell provided with the plurality of layers.

10. The memory system according to claim 9, wherein the control circuit is configured to perform the initial write operation collectively on all effective memory cells provided with the plurality of memory pillars.

11. The memory system according to claim 9, wherein the control circuit is configured to perform the initial write operation collectively on a part of memory cell among all effective memory cells provided with the plurality of memory pillars.

12. The memory system according to claim 10, wherein the control circuit is configured to perform a program operation and a verify operation repeatedly in the initial write operation a plurality of times.

13. The memory system according to claim 10, wherein
the control circuit is configured to perform a verify operation repeatedly in the initial write operation based on a first voltage value, and
the first voltage is higher than an average voltage of a threshold voltage distribution configured by the initial write operation.
